(19) United States
(12) Patent Application Publication
(10) Pub. No.: US 2010/0045846 A1
(43) Pub. Date: Feb. 25, 2010

(54) IMAGE PICKUP DEVICE, METHOD OF MANUFACTURING THE SAME, AND MOBILE TERMINAL DEVICE

(76) Inventors: Hiroshi Nishizawa, Kanagawa (JP); Tatsuo Kobayashi, Kanagawa (JP); Kouji Ugawa, Kanagawa (JP)

Correspondence Address: MCDERMOTT WILL & EMERY LLP, 600 13TH STREET, NW, WASHINGTON, DC, 20005-3096, US

(21) Appl. No.: 12/523,695

(22) PCT Filed: Feb. 1, 2008
(86) PCT No.: PCT/JP2008/051644

§ 371 Date: Jul. 17, 2009

(30) Foreign Application Priority Data
Feb. 2, 2007 (JP) 2007-024264
Mar. 8, 2007 (JP) 2007-058469
Mar. 8, 2007 (JP) 2007-058470

(51) Int. Cl. H04N 5/225; H01L 21/50

(52) U.S. Cl. 348/340; 438/65; 257/E21.499

(57) ABSTRACT

An excellent image pickup device whose size and thickness are reduced is realized with a simple structure, and thus the slimming down of a mobile terminal device is accomplished. A slim image pickup device in which a plate-like member 8 having a stepped portion 8A around an opening portion 9, an optical filter 5 arranged on an inside of the stepped portion 8A to cover the opening portion, a wiring substrate 7 arranged on an outside of the stepped portion to be fitted, a semiconductor image pickup element 6 flip-chip mounted on the wiring substrate 7, and a lens 2 positioned/fitted on the plate-like member 8 are provided is realized.

### TECHNICAL FIELD

The present invention relates to an image pickup device, a method of manufacturing the same, and a mobile terminal device and, more particularly, an image pickup device used in a camera for a mobile equipment and capable of achieving a slimming down and a mobile terminal device using this image pickup device.

### BACKGROUND ART

In the prior art, as a small-sized image pickup device used in a cellular phone with camera, or the like, such an image pickup device has been proposed that, because an image pickup element is flip-chip mounted on one surface of a translucent substrate on which wiring patterns are formed and also a lens unit is mounted on a substrate surface on the opposite side, its thickness is reduced by a dimension of the package that hermetically seals the image pickup element (Patent Literature 1). In this image pickup element, the translucent substrate, the image pickup element, and the lens unit as constituent components are mounted at a higher density in the thickness direction of the module, and therefore the slimming down of the device can be achieved. Also, in above Patent Literature 1, it is set forth that the image pickup element can be implemented in such a manner that, because an optical filtering function is provided to the translucent substrate, there is no need to incorporate an optical filter substrate into the lens unit.

Also, the image pickup device in which the image pickup element is mounted on a flexible substrate has been proposed (Patent Literature 2). In this image pickup device, the image pickup element and the lens barrel are fixed via a translucent member to put the flexible substrate between them. Therefore, the image pickup element and the end surface of the lens barrel can be set in parallel with each other. As a result, the image pickup element can be aligned easily with an optical axis of the lens barrel without influence of a flexibility of the flexible substrate.

Patent Literature 1: JP-A-2001-203913 (page 2 [0009], FIG. 2)

Patent Literature 2: JP-A-2005-278033 (page 4 [0015], FIG. 2)

### DISCLOSURE OF THE INVENTION

### Problems that the Invention is to Solve

However, in the conventional image pickup device set forth in Patent Literature 1, the wiring patterns are formed directly on the translucent substrate, and the conductive film is formed on the translucent substrate by the vapor deposition or the plating and then the pattern formation is made by the etching, or the like. Normally various stresses due to heat, stress, PH, and the like are applied during the film formation and the pattern formation. Therefore, in order to stabilize the optical characteristic against these stresses and get the optical isotropy, the glass is mainly employed as the translucent substrate. In constructing the substrate of the optical filter with a resin, the above stresses must be considered sufficiently, which acts as a factor to restrict a flexibility of design. Meanwhile, it has been known that dielectric films whose refractive index is different respectively are stacked on the base material such as a translucent resin, or the like in necessary layer numbers, and thus the optical filter on which no conductive pattern is provided is formed as the reflection-type filter. Here, it is assumed that the “optical isotropy” denotes that the substrate has no directivity in transmittance, refractive index, etc.

Also, the optical glass is the fragile material. Thus, when this optical glass is formed thinly, the stress cracking is easily caused by handling, impact, or the like. Therefore, the translucent substrate having a thickness to some extent must be employed to ensure a strength, which acts as a factor to obstruct the slimming down. In particular, the absorption-type infrared cut glass is implemented by doping a divalent copper ion, or the like. In this case, it has been known that, when a thickness us reduced, an optical length is shortened and thus infrared rays cannot be sufficiently absorbed. Normally a thickness in excess of about 1 mm is needed. In this manner, a desired optical length must be ensured to cut the infrared rays, which acts as a major factor to obstruct the slimming down of the image pickup device.

In the image pickup device set forth in Patent Literature 2, as described above, the flexible substrate is put between the lens barrel whose end surface is provided perpendicularly to the optical axis in the optical system and the surface of the image pickup element. Therefore, the image pickup element and the end surface of the lens barrel can be set in parallel with each other by utilizing the fact that both surfaces of the flexible substrate are in parallel. Accordingly, the optical axis perpendicular to the end surface of the lens barrel can be aligned easily with the optical axis of the image pickup element.

In the case of this device, the optical axes can be aligned easily with each other in an assembled state. However, the care of the handling must be taken sufficiently in the assembling process such that the optical axes of the image pickup element and the optical system are not affected by the flexibility of the flexible substrate. Accordingly, there is such a tendency that the workability and the working steps containing a holding jig are restricted.

Also, it is set forth that the opening portion can be reinforced by pasting together a reinforcing plate around the opening portion of the flexible substrate. The reinforcing plate and the opening portion must be pasted together with good accuracy not to produce an eclipse in surrounding pixels. Also, a parallelism of the flexible substrate obtained when the reinforcing plate is pasted on the substrate is changed depending upon variations in thickness of the adhesive layer and the reinforcing plate as well as the flexible substrate itself (constituent members such as base film, copper foil, adhesive layer, cover film, and the like). Since these variations in thickness degrade an accuracy of the optical axis, the sufficient-care must be taken.

For the reasons mentioned above, such a problem existed that a cost of the constituent components is increased. In this manner, in the conventional image pickup device, the problem lies in the slimming down, the cost reduction, and the workability.

The present invention has been made in view of the above circumstances, and it is an object of the present invention to provide an image pickup device capable of achieving a slimming down and a size reduction with high precision and high reliability at a low cost.

Also, it is another object of the present invention to provide an excellent image pickup device having good assembling workability and allowing a size reduction of a cellular phone.

### Means for Solving the Problems

Therefore, in order to attain the above object, an image pickup device of the present invention includes a plate-like member equipped with an opening portion and having a stepped portion around the opening portion; an optical filter provided on an inside of the stepped portion to cover the opening portion; a wiring substrate arranged to be fitted on the stepped portion; and an image pickup device mounted on the wiring substrate.

According to this configuration, a positional relationship between the optical filter arranged on the inside of the stepped portion and the wiring substrate arranged on the outside of the stepped portion is regulated by the stepped portion. Therefore, a positional precision can be kept highly by a combination of these components without a particular jig, or the like. Also, the wiring substrate is fitted into the outside of the stepped portion on the plate-like member. Therefore, the wiring substrate can be fixed with extremely good positional precision. Also, in mounting the semiconductor image pickup element on the wiring substrate, normally the semiconductor image pickup element is positioned by using a recognition mark attached to the mounting substrate and the semiconductor image pickup element respectively. Therefore, the semiconductor image pickup element can be mounted on the wiring substrate with good precision. As a result, positioning of the mounting substrate can be done easily and surely. Further, because the optical filter is mounted on the inside of the stepped portion, the plate-like member and the optical filter can be arranged to overlap with each other in the optical axis direction. As a result, the slimming down of the image pickup device can be attained.

Also, the present invention contains the above image pickup device further includes a lens positioned and fitted on the plate-like member.

According to this configuration, since the lens is positioned/fitted on the plate-like member, the plate-like member serves as a basis of respective assemblies. Therefore, a tolerance is never accumulated, and the optical axis can be set with good precision.

Also, the present invention contains the above image pickup device in which the image pickup element is flip-chip mounted on the wiring substrate.

According to this configuration, the image pickup element is flip-chip mounted on the wiring substrate, and thus the slimming down can be attained. Especially, in the flip-chip mounting, normally the semiconductor image pickup element is positioned by using the recognition mark attached to the mounting substrate and the semiconductor image pickup element respectively. Therefore, the semiconductor image pickup element can be mounted on the wiring substrate with good precision. Therefore, positioning of the mounting substrate can be done easily without fail. The mounting can be carried out when the image pickup element may be surface-mounted on the wiring substrate not to use the flip-chip mounting and then may be wire-bonded to the pads that are formed on a surface on the side that opposes to the light receiving face of the image pickup element substrate.

Also, the present invention contains the above image pickup device in which the plate-like member is formed of a metal plate, and the stepped portion is obtained by a half die cutting.

According to this configuration, the plate-like member can be formed by using the metal plate as the material with a simple press working, and extremely good workability can be get at a low cost. Also, since a dimensional precision is high and the number of steps can be reduced, managed man-hours can be reduced and also a cost reduction can be implemented. In this case, since commonly a Young's of modulus of a metal is high in contrast to a resin, the plate-like member can be constructed thin to get the similar strength. Therefore, this plate-like member is effective to the slimming down of the image pickup device. In addition, since a temperature anisotropy of the metal is small in contrast to a resin, a stress imposed on the flip-chip mounting portion by a temperature can be reduced. As a result, this plate-like member is suitable for improving reliability of the image pickup device.

Also, the present invention contains the above image pickup device in which the metal plate is formed of metal material including nickel as a major component.

According to this configuration, since the electromagnetic shielding property can be enhanced, the EMI characteristic can be improved. Accordingly, a picture quality that is stable against an external noise and has a good quality can be obtained. Also, since the unwanted emissions to the mobile terminal device can be reduced, a higher density packing of the mobile terminal device can be realized, and a downsizing of the mobile terminal can be achieved.

Also, the present invention contains the above image pickup device in which the metal plate is formed of metal material including aluminum as a major component.

According to this configuration, a weight reduction can be attained, and an impact resistance against a drop of the image pickup device, or the like can be improved. Also, a mass of the mobile terminal device can be reduced. Further, a mass of the image pickup device can also be reduced. As a result, a thickness of the case of the mobile terminal device for holding the image pickup device can be reduced, weight reduction/downsizing of the mobile terminal device can be realized, and convenience can be improved.

Also, the present invention contains the above image pickup device in which the optical filter is of a reflection type.

According to this configuration, since the optical filter having the equal optical characteristic (filtering characteristic) can be constructed thinner than the absorption type filter, this optical filter is useful for the slimming down of the image pickup device. Also, when the optical filter is constructed by using a resin as the base material and then coating a surface with a dielectric multi-layered film, even the thin optical filter is hard to break unlike the fragile material such as a glass, or the like, and therefore the optical filter can be can be further thinned. In this case, because of stress cracking resistance, the handling in the assembling, or the like can be improved. As a result, the automatic assembling can be easily realized.

Also, the present invention contains the above image pickup device in which the stepped portion is obtained by an etching process.

According to this configuration, a stress applied to the plate-like member in working can be reduced, and the plate-like member of higher precision can be implemented. Accordingly, a precision of the flip-chip mounting portion can be improved much more, and reliability of the image pickup device can be improved on account of improvement of the precision in the flip-chip mounting. Also, because the stepped portion is formed by the etching process, the inner side portion and the outer side portion can be shaped independently. Also, because the surface processed by the etching becomes uneven, a reflection can be prevented optically. Accordingly, a flare or a ghost generated at the end surface of the opening portion can be reduced, and the image pickup device of high quality can be obtained. In this case, an unevenness of the surface on which the optical filter is mounted can yield an expansion of an adhesive area. Therefore, an adhesive strength in adhering/mounting the small-sized optical filter can be increased.

Also, a method of manufacturing an image pickup device of the present invention, includes: providing a plate-like member that is equipped with an opening portion and has a stepped portion around the opening portion; attaching an optical filter to the plate-like member to cover the opening portion on an inside of the stepped portion; fitting a wiring substrate to be fitted on the stepped portion; and mounting an image pickup element on the wiring substrate such that a light receiving face is directed to an optical filter side. The process of fitting the optical filter includes: filling an adhesive in an inner wall on an inside of the stepped portion; and self-aligning the optical filter in accordance with a meniscus that is formed by the adhesive in a clearance between the inner wall of the stepped portion and the optical filter.

According to this method, the optical filter is self-aligned by a meniscus (crosslink) produced by the adhesive that is filled in a clearance between the optical filter and the inner wall of the stepped portion on the inner side. The optical filter is aligned such that the optical filter is balanced by a surface tension of the adhesive that is filled in a clearance between the inner wall of the stepped portion on the inner side and the periphery of the optical filter. Therefore, the optical filter can be aligned on the inside of the stepped portion not to use the special positioning jig, and the steps can be simplified. Also, since the optical filter can be automatically aligned on the inside of the stepped portion, positional displacement of the optical filter can be reduced, an assembling variation of the image pickup device can be reduced, and the image pickup device of stable quality can be obtained. Further, since the positional displacement of the optical filter can be reduced, a size of the optical filter can be reduced within an optically available range. Accordingly, even though the optical filter employs the glass as the base material, a size reduction of such filter can be achieved. As a result, the optical filter can be improved in strength even when the glass is thinned, and also the slimming down of the image pickup device can be achieved.

Also, a mobile terminal device is constructed by using the image pickup device set forth above.

According to this configuration, the slimming down of the image pickup device can be achieved, and improvement of the precision can be attained. Therefore, the slimming down of the mobile terminal device can be achieved by using the image pickup device of high reliability. Also, reliability of the image pickup device can be improved, and thus reliability of the mobile terminal device can be enhanced.

Therefore, in order to attain the above object, an image pickup device of the present invention includes a plate-like member equipped with an opening portion and having a recess portion around the opening portion on a first surface, and a second surface opposing to the first surface is formed flat; an optical filter positioned/secured to the recess portion formed on the first surface to cover the opening portion; a wiring substrate having an opening correspond to the opening portion in the plate-like member, and arranged to be fitted on the stepped portion; and a semiconductor image pickup element mounted on the wiring substrate.

According to this configuration, the plate-like member is a flat plate, and the recess portion into which the optical filter is fitted is provided. Therefore, positioning is made easy and manufacturing workability is good. Also, since the optical filter is fitted in the recess portion formed in the plate-like member, the slimming down can be achieved. Also, the optical filter is regulated by the recess portion. Therefore, a positional precision can be kept highly by a combination of these components not to use the particular jig, or the like. Also, in mounting the semiconductor image pickup element on the wiring substrate, normally the semiconductor image pickup element is positioned by using the recognition mark attached to the mounting substrate and the semiconductor image pickup element respectively. Therefore, the semiconductor image pickup element can be mounted on the wiring substrate with good precision. As a result, positioning of the mounting substrate can be done easily and surely.

Also, the present invention contains the above image pickup device in which the optical filter is self-aligned by the adhesive that is filled in a clearance between the recess portion and the optical filter.

According to this configuration, the optical filter is self-aligned with the recess portion by a surface tension of the adhesive that is filled between the recess portion provided on the plate-like member and the optical filter. Therefore, positioning can be executed not to use the particular jig. As a result, improvement of the workability and improvement of a mounting precision of the optical filter can be achieved.

Also, the image pickup device of the present invention further includes a lens positioned/fitted on the first surface of the plate-like member. According to this configuration, since the lens is positioned/fitted on the plate-like member, the plate-like member serves as a basis of respective assemblies. Therefore, a tolerance is never accumulated, and the optical axis can be set with good precision.

Also, the present invention contains the above image pickup device in which the image pickup element is flip-chip mounted on the wiring substrate.

According to this configuration, the image pickup element is flip-chip mounted on the wiring substrate, and thus the slimming down can be attained. Especially, in the flip-chip mounting, normally the semiconductor image pickup element is positioned by using the recognition mark attached to the mounting substrate and the semiconductor image pickup element respectively. Therefore, the semiconductor image pickup element can be mounted on the wiring substrate with good precision. Therefore, positioning of the mounting substrate can be done easily without fail. The mounting can be carried out when the image pickup element may be surface-mounted on the wiring substrate not to use the flip-chip mounting and then may be wire-bonded to the pads that are formed on a surface on the side that opposes to the light receiving face of the image pickup element substrate.

Also, the present invention contains the above image pickup device in which the plate-like member is formed of a metal plate, and the stepped portion is formed by a thickness removing process using the press working.

According to this configuration, the plate-like member can be formed by using the metal plate as the material with a simple press working, and extremely good workability can be get at a low cost. Since the stepped portion is formed by the thickness removing process, the surface after the process can be formed as the flat surface. Also, since a dimensional precision is high and the number of steps can be reduced, managed man-hours can be reduced and also a cost reduction can be implemented. In this case, since commonly a Young's of modulus of a metal is high in contrast to a resin, the plate-like member can be constructed thin to get the similar strength. Therefore, this plate-like member is effective to the slimming down of the image pickup device. In addition, since a temperature anisotropy of the metal is small in contrast to a resin, a stress imposed on the flip-chip mounting portion by a temperature can be reduced. As a result, this plate-like member is suitable for improving reliability of the image pickup device.

Also, the present invention contains the above image pickup device in which the recess portion is formed by an etching process.

According to this configuration, a stress applied to the plate-like member in working can be reduced, and the plate-like member of higher precision can be implemented. Accordingly, a precision of the flip-chip mounting portion can be improved much more, and reliability of the image pickup device can be improved on account of improvement of the precision in the flip-chip mounting. Also, because the surface processed by the etching becomes uneven, a reflection can be prevented optically. Accordingly, a flare or a ghost generated at the end surface of the opening portion can be reduced, and the image pickup device of high quality can be obtained. In this case, an unevenness of the surface on which the optical filter is mounted can yield an expansion of an adhesive area. Therefore, an adhesive strength in adhering/mounting the small-sized optical filter can be increased.

Also, the present invention contains the above image pickup device in which the metal plate is formed of metal material including nickel as a major component.

According to this configuration, since the electromagnetic shielding property can be enhanced, the EMI characteristic can be improved. Accordingly, a picture quality that is stable against an external noise and has a good quality can be obtained. Also, since the unwanted emissions to the mobile terminal device can be reduced, a higher density packing of the mobile terminal device can be realized, and a downsizing of the mobile terminal can be achieved.

Also, the present invention contains the above image pickup device in which the metal plate is formed of metal material including aluminum as a major component.

According to this configuration, a weight reduction can be attained, and an impact resistance against a drop of the image pickup device, or the like can be improved. Also, a mass of the mobile terminal device can be reduced. Further, a mass of the image pickup device can also be reduced. As a result, a thickness of the case of the mobile terminal device for holding the image pickup device can be reduced, weight reduction/downsizing of the mobile terminal device can be realized, and convenience can be improved.

Also, the present invention contains the above image pickup device in which the optical filter is of a reflection type.

According to this configuration, since the optical filter having the equal optical characteristic (filtering characteristic) can be constructed thinner than the absorption type filter, this optical filter is useful for the slimming down of the image pickup device. Also, when the optical filter is constructed by using a resin as the base material and then coating a surface with a dielectric multi-layered film, even the thin optical filter is hard to break unlike the fragile material such as a glass, or the like, and therefore the optical filter can be can be further thinned. In this case, because of stress cracking-resistance, the handling in the assembling, or the like can be improved. As a result, the automatic assembling can be easily realized.

Also, a method of manufacturing an image pickup device of the present invention, includes: preparing a plate-like member that is equipped with an opening portion and has a recess portion around the opening portion on a first surface, and a second surface opposing to the first surface is formed flat; fitting an optical filter in the recess portion formed in the first surface of the plate-like member to cover the opening portion; fitting a wiring substrate on the second surface side of the plate-like member; mounting an image pickup element on the wiring substrate such that a light receiving face is directed to an optical filter side; and fitting a lens on a first surface side of the plate-like member.

Also, in the method of manufacturing the image pickup device of the present invention, the process of fitting the optical filter includes: filling an adhesive in an inner wall of the recess portion such that the optical filter is self-aligned by a meniscus formed by the adhesive in a clearance between the inner wall of the stepped portion and the optical filter.

According to this method, the optical filter is self-aligned by a meniscus (crosslink) produced by the adhesive that is filled in a clearance between the optical filter and the inner wall of the stepped portion on the inner side. The optical filter is aligned such that the optical filter is balanced by a surface tension of the adhesive that is filled in a clearance between the inner wall of the stepped portion on the inner side and the periphery of the optical filter. Therefore, the optical filter can be aligned on the inside of the stepped portion not to use the special positioning jig, and the steps can be simplified. Also, since the optical filter can be automatically aligned on the inside of the stepped portion, positional displacement of the optical filter can be reduced, an assembling variation of the image pickup device can be reduced, and the image pickup device of stable quality can be obtained. Further, since the positional displacement of the optical filter can be reduced, a size of the optical filter can be reduced within an optically available range. Accordingly, even though the optical filter employs the glass as the base material, a size reduction of such filter can be achieved. As a result, the optical filter can be improved in strength even when the glass is thinned, and also the slimming down of the image pickup device can be achieved.

Also, the method of manufacturing the image pickup device of the present invention further includes: forming the plate-like member in a state that the plate-like member is coupled partially via a tie rod from the process of providing the plate-like member to the process of fitting the lens, then assembling the plate-like member in a coupled state, and then removing the tie rod finally.

According to this configuration, the plate-like member is flat. Therefore, its handling is easy in a sheet fashion or a roll fashion, and the assembling can be done in a coupled state. If the plate-like member is divided individually after assembled, the plate-like member can be formed easily with extremely good positional precision and good workability.

Also, in the method of manufacturing the image pickup device of the present invention, the assemble is done in a coupled state while winding the plate-like member between a feed roller and a winding roller.

According to this configuration, the plate-like member is flat. Therefore, the assembling can be done by winding, and can be formed easily with extremely good positional precision.

Also, a mobile terminal device is constructed by using the image pickup device set forth above.

According to this configuration, the slimming down of the image pickup device can be achieved, and improvement of the precision can be attained. Therefore, the slimming down of the mobile terminal device can be achieved by using the image pickup device of high reliability. Also, reliability of the image pickup device can be improved, and thus reliability of the mobile terminal device can be enhanced.

### ADVANTAGES OF THE INVENTION

Therefore, in order to attain the above object, an image pickup device of the present invention, includes a plate-like member in which a stepped portion having an opening in a center is provided; an optical filter arranged in a recess portion on an inside of the stepped portion to cover the opening portion; a wiring substrate having an opening correspond to the optical filter, and arranged on a first surface of the plate-like member; a semiconductor image pickup element mounted on the wiring substrate; and a lens arranged on a second surface of the plate-like member; wherein the opening and the lens are arranged to overlap with each other in an optical axis direction.

According to this configuration, since the lens, the optical filter, and the plate-like member can be positioned to overlap with each other in the optical axis direction, the slimming down can be achieved much more. Also, the optical filter is arranged in the recess on the inside of the stepped portion. Therefore, the position of the optical filter is regulated by the stepped portion, and thus a positional precision can be kept highly by a combination of these components without a particular jig, or the like. Also, the wiring substrate is fitted into the outside of the stepped portion on the plate-like member. Therefore, the wiring substrate can be fixed with extremely good positional precision. Also, in mounting the semiconductor image pickup element on the wiring substrate, normally the semiconductor image pickup element is positioned by using a recognition mark attached to the mounting substrate and the semiconductor image pickup element respectively. Therefore, the semiconductor image pickup element can be mounted on the wiring substrate with good precision. As a result, positioning of the mounting substrate can be done easily without fail. Also, since the lens is positioned/fitted on the plate-like member, the plate-like member serves as a basis of respective assemblies. Therefore, a tolerance is never accumulated, and the optical axis can be set with good precision.

Also, the present invention contains the above image pickup device in which the optical filter is self-aligned by the adhesive that is filled in a clearance between the recess portion and the optical filter.

According to this configuration, the optical filter is self-aligned with the recess portion by a surface tension of the adhesive that is filled between the recess portion provided on the plate-like member and the optical filter. Therefore, positioning can be executed not to use the particular jig. As a result, improvement of the workability and improvement of a mounting precision of the optical filter can be achieved.

Also, the present invention contains the above image pickup device in which the wiring substrate has a hole that is fitted on an outer periphery of the optical filter fitted in a hole in the plate-like member, and is positioned by fitting the hole on the optical filter.

According to this configuration, the wiring substrate can be positioned with respect to the optical filter without the jig. Therefore, the positioning can be made easy and improvement of a precision can be attained. Also, the further slimming down can be achieved.

Also, the present invention contains the above image pickup device in which the image pickup element is flip-chip mounted on the wiring substrate.

According to this configuration, the image pickup element is flip-chip mounted on the wiring substrate, and thus the slimming down can be attained. Especially, in the flip-chip mounting, normally the semiconductor image pickup element is positioned by using the recognition mark attached to the mounting substrate and the semiconductor image pickup element respectively. Therefore, the semiconductor image pickup element can be mounted on the wiring substrate with good precision. Therefore, positioning of the mounting substrate can be done easily without fail. The mounting can be carried out when the image pickup element may be surface-mounted on the wiring substrate not to use the flip-chip mounting and then may be wire-bonded to the pads that are formed on a surface on the side that opposes to the light receiving face of the image pickup element substrate.

Also, the present invention contains the above image pickup device in which the plate-like member is formed of a metal plate, and the stepped portion is obtained by a half die cutting.

According to this configuration, the plate-like member can be formed by using the metal plate as the material with a simple press working, and extremely good workability can be get at a low cost. Also, since a dimensional precision is high and the number of steps can be reduced, managed man-hours can be reduced and also a cost reduction can be implemented. In this case, since commonly a Young's of modulus of a metal is high in contrast to a resin, the plate-like member can be constructed thin to get the similar strength. Therefore, this plate-like member is effective to the slimming down of the image pickup device. In addition, since a temperature anisotropy of the metal is small in contrast to a resin, a stress imposed on the flip-chip mounting portion by a temperature can be reduced. As a result, this plate-like member is suitable for improving reliability of the image pickup device.

Also, the present invention contains the above image pickup device in which the stepped portion is obtained by an etching process.

According to this configuration, a stress applied to the plate-like member in working can be reduced, and the plate-like member of higher precision can be implemented. Accordingly, a precision of the flip-chip mounting portion can be improved much more, and reliability of the image pickup device can be improved on account of improvement of the precision in the flip-chip mounting. Also, because the stepped portion is formed by the etching process, the inner side portion and the outer side portion can be shaped independently. Also, because the surface processed by the etching becomes uneven, a reflection can be prevented optically. Accordingly, a flare or a ghost generated at the end surface of the opening portion can be reduced, and the image pickup device of high quality can be obtained. In this case, an unevenness of the surface on which the optical filter is mounted can yield an expansion of an adhesive area. Therefore, an adhesive strength in adhering/mounting the small-sized optical filter can be increased.

Also, the present invention contains the above image pickup device in which the metal plate is formed of metal material including nickel as a major component.

According to this configuration, since the electromagnetic shielding property can be enhanced, the EMI characteristic can be improved. Accordingly, a picture quality that is stable against an external noise and has a good quality can be obtained. Also, since the unwanted emissions to the mobile terminal device can be reduced, a higher density packing of the mobile terminal device can be realized, and a downsizing of the mobile terminal can be achieved.

Also, the present invention contains the above image pickup device in which the metal plate is formed of metal material including aluminum as a major component.

According to this configuration, a weight reduction can be attained, and an impact resistance against a drop of the image pickup device, or the like can be improved. Also, a mass of the mobile terminal device can be reduced. Further, a mass of the image pickup device can also be reduced. As a result, a thickness of the case of the mobile terminal device for holding the image pickup device can be reduced, weight reduction/downsizing of the mobile terminal device can be realized, and convenience can be improved.

Also, the present invention contains the above image pickup device in which the optical filter is a reflection-type optical filter.

According to this configuration, since the optical filter having the equal optical characteristic (filtering characteristic) can be constructed thinner than the absorption type filter, this optical filter is useful for the slimming down of the image pickup device. Also, when the optical filter is constructed by using a resin as the base material and then coating a surface with a dielectric multi-layered film, even the thin optical filter is hard to break unlike the fragile material such as a glass, or the like, and therefore the optical filter can be can be further thinned. In this case, because of stress cracking resistance, the handling in the assembling, or the like can be improved. As a result, the automatic assembling can be easily realized.

Also, a method of manufacturing an image pickup device of the present invention, includes: providing a plate-like member that is equipped with an opening portion in a center and has a stepped portion around the opening portion; fitting an optical filter in a recess on an inside of the stepped portion of the plate-like member to cover the opening portion; fitting a wiring substrate that has a hole corresponding to the optical filter and arranged on a first surface of the plate-like member; mounting an image pickup element on the wiring substrate such that a light receiving face is directed to an optical filter side; and fitting a lens such that the lens fitted onto a second surface of the plate-like member is able to overlap in an optical axis.

Also, in the method of manufacturing the image pickup device of the present invention, the process of fitting the optical filter includes: filling an adhesive in an inner wall of the recess portion such that the optical filter is self-aligned by a meniscus formed by the adhesive in a clearance between the inner wall of the stepped portion and the optical filter.

According to this method, the optical filter is self-aligned by a meniscus (crosslink) produced by the adhesive that is filled in a clearance between the optical filter and the inner wall of the stepped portion on the inner side. The optical filter is aligned such that the optical filter is balanced by a surface tension of the adhesive that is filled in a clearance between the inner wall of the stepped portion on the inner side and the periphery of the optical filter. Therefore, the optical filter can be aligned on the inside of the stepped portion not to use the special positioning jig, and the steps can be simplified. Also, since the optical filter can be automatically aligned on the inside of the stepped portion, positional displacement of the optical filter can be reduced, an assembling variation of the image pickup device can be reduced, and the image pickup device of stable quality can be obtained. Further, since the positional displacement of the optical filter can be reduced, a size of the optical filter can be reduced within an optically available range. Accordingly, even though the optical filter employs the glass as the base material, a size reduction of such filter can be achieved. As a result, the optical filter can be improved in strength even when the glass is thinned, and also the slimming down of the image pickup device can be achieved.

Also, a mobile terminal device is constructed by using the image pickup device set forth above.

According to this configuration, the slimming down of the image pickup device can be achieved, and improvement of the precision can be attained. Therefore, the slimming down of the mobile terminal device can be achieved by using the image pickup device of high reliability. Also, reliability of the image pickup device can be improved, and thus reliability of the mobile terminal device can be enhanced.

As described above, an image pickup device of the present invention, includes a plate-like member having a stepped portion around an opening portion; an optical filter arranged in an inside of the stepped portion to cover the opening portion; a wiring substrate arranged to be fitted on an outside of the stepped portion; a semiconductor image pickup element flip-chip mounted on the wiring substrate; and a lens positioned/fitted on the plate-like member; wherein the optical-filter, the lens, the substrate on which the semiconductor image pickup element is mounted are positioned in terms of one component to enhance a optical axis precision. Also, because the optical filter is mounted on the inside of the stepped portion, the plate-like member and the optical filter are arranged to overlap with each other in an optical axis direction. Therefore, the slimming down of the image pickup device can be achieved.

According to the image pickup device of the present invention, the plate-like member can be formed by using the flat plate member with good positional precision. Therefore, the slimming down of the image pickup device can be done easily, and the image pickup device can be formed easily without distortion.

Also, according to the image pickup device of the present invention, the plate-like member and the optical filter are arranged to overlap with each other in the optical axis direction. Therefore, the further slimming down of the image pickup device can be achieved.

### BRIEF DESCRIPTION OF THE DRAWINGS

FIG. 1 A pertinent perspective view of an image pickup device of Embodiment 1 of the present invention.

FIG. 2 A sectional view taken along an X-X line in the image pickup device in FIG. 1.

FIG. 3 An enlarged sectional view of an A portion of the image pickup device in FIG. 2.

FIG. 4 An enlarged sectional view of a B portion of the image pickup device in FIG. 3.

FIG. 5 A pertinent enlarged sectional view of an image pickup device of Embodiment 2 of the present invention.

FIG. 6 A sectional view taken along an X-X line in an image pickup device of Embodiment 3 of the present invention.

FIG. 7 An enlarged sectional view of an A portion in FIG. 6.

FIG. 8 An enlarged sectional view of a B portion in FIG. 7.

FIG. 9 A pertinent enlarged sectional view of an image pickup device of Embodiment 4 of the present invention.

FIG. 10 A sectional view taken along an X-X line in an image pickup device of Embodiment 5 of the present invention.

FIG. 11 An enlarged sectional view of an A portion in FIG. 10.

FIG. 12 An enlarged sectional view of a B portion in FIG. 11.

FIG. 13 A pertinent enlarged sectional view of an image pickup device of Embodiment 6 of the present invention.

FIG. 14 An external view of a cellular phone.

### DESCRIPTION OF REFERENCE NUMERALS AND SIGNS

1 image pickup device
2, 2a, 2b aspherical lens
3 lens holder
3a diaphragm
3b screw
4 base
4a contact surface
4b screw
5 optical filter
6 semiconductor image pickup element
6a pad
7 wiring substrate
7a conductive pattern
7b hole
8, 18 plate-like member
8A stepped portion
8a, 8b, 18a, 18b wall surface
8c plane surface
9 opening portion
11 adhesive
15 FPC
16 connector
20 sealing agent
21 bump
30 cellular phone
31 uppercase
32 lower case
33 speaker
34 display screen
35 hinge
36 antenna
37 input key
37a shooting key
38 image pickup device
39 microphone

### BEST MODE FOR CARRYING OUT THE INVENTION

### Embodiment 1

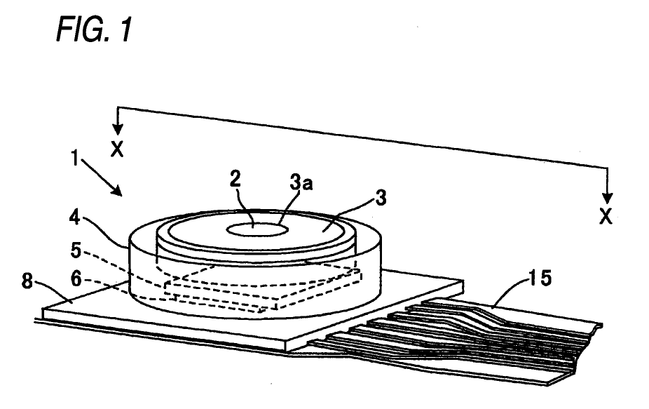

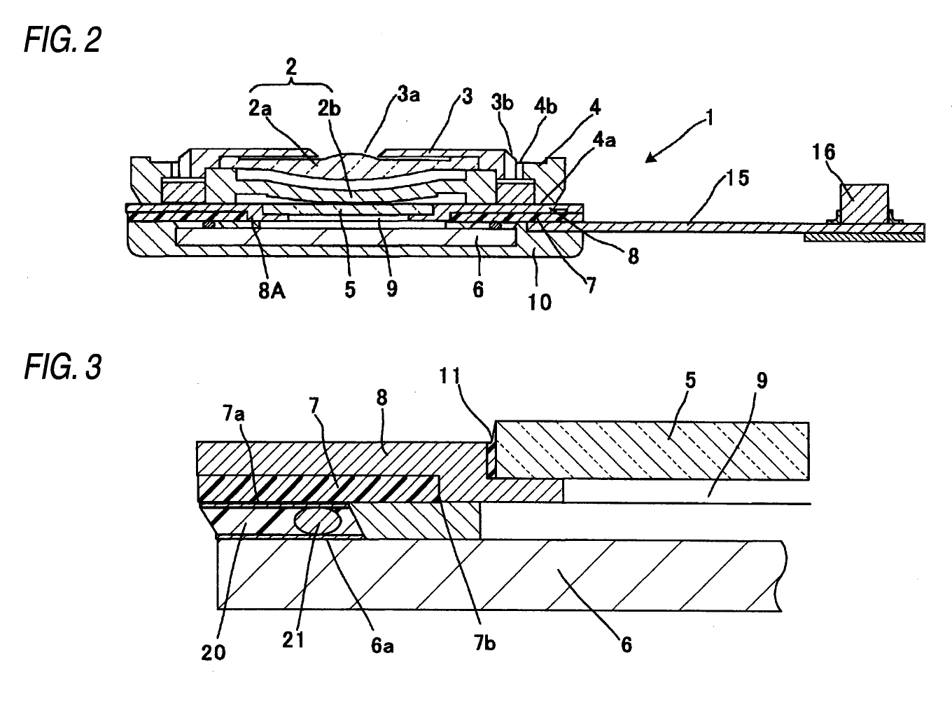

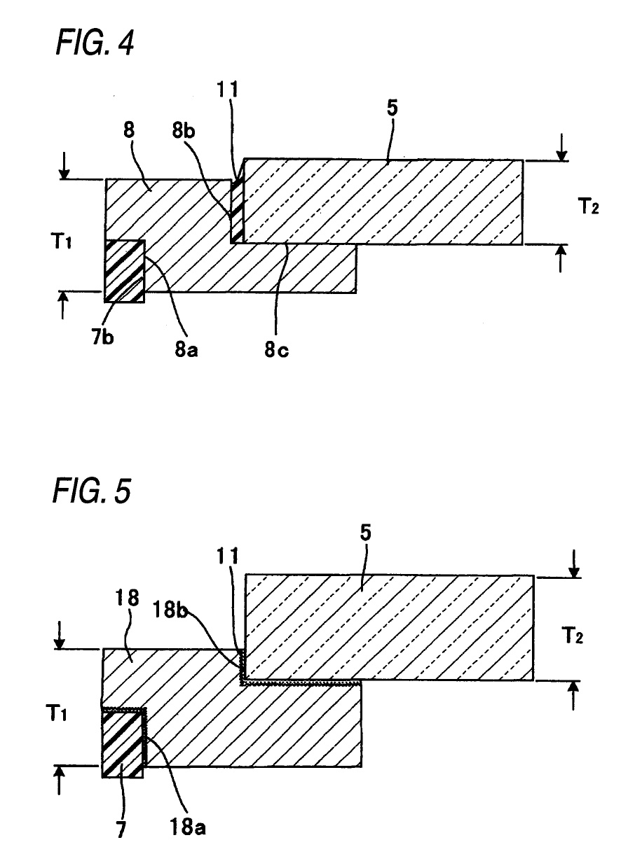

Embodiment 1 of the present invention will be explained with reference to the drawings hereinafter. FIG. 1 is a pertinent perspective view of an image pickup device of the present invention. FIG. 2 is a sectional view taken along an X-X line in FIG. 1 of the image pickup device of the present invention. FIG. 3 is an enlarged sectional view of an A portion of the image pickup device in FIG. 2. FIG. 4 is an enlarged sectional view of a B portion of the image pickup device in FIG. 3.

FIG. 1 is a perspective view showing a pertinent portion of an image pickup device 1. The image pickup device 1 has a lens holder 3 having a diaphragm 3a in its center portion on the subject side (upper side in FIG. 1), and a base 4 for holding the lens holder 3 to move in the optical axis. A lens 2 is adhered/secured to the inside of the lens holder 3. The lens 2 is positioned by a positioning means (not shown) via the base 4, and is adhered/secured to a plate-like member (plate-like holding member) 8. An optical filter 5 and a semiconductor image pickup element 6 as an imaging element are fitted to the plate-like member 8 respectively. The image pickup device 1 is constructed such that a light from a subject passes through the diaphragm 3a and is converged by the lens 2, then a transmission of unnecessary infrared lights is limited by the optical filter 5, and then a resultant light is subjected to a photoelectric conversion by the semiconductor image pickup element 6 and is picked up as a desired electric signal.

A configuration of the image pickup device 1 will be explained in more detail with reference to FIG. 2 to FIG. 4 hereunder. A stepped portion 8A is provided to a center portion of the plate-like member 8, and an opening portion 9 is formed in its center portion. The opening portion 9 is formed like a rectangle having roughly a ratio of 3:4 to correspond to a shooting area of the semiconductor image pickup element 6. The optical filter 5 is adhered and fixed to the inside of the stepped portion 8A to cover (block) the opening portion 9. A wiring substrate 7 is arranged on the outside of the stepped portion 8A to be fitted thereon, and the semiconductor image pickup element 6 is flip-chip mounted on the wiring substrate 7. Also, the lens 2 is positioned by a boss (not shown), or the like, and is fitted to the plate-like member 8 via the base 4.

In the optical filter 5, an IR (Infra Red) cut coating is applied to one surface of a base material that is made of glass of 0.15 mm thick. An AR (Anti Reflection) coating for reflection prevention may be applied to the other surface if necessary. A coefficient of thermal expansion is about 7×10⁻⁶/° C. As the IR cut coating, for example, a dielectric film formed of silicon dioxide (SiO₂), titanium oxide (TiO₂), or the like and having a film thickness of almost several tens nm is stacked in several tens layers. The IR cut coating provides the spectral characteristic whose half-width wavelength is about 650 nm and in which a transmission of the light having the longer wavelength than this wavelength is sufficiently suppressed. As the AR coating for reflection prevention, for example, aluminum oxide (Al₂O₃), magnesium fluoride (MgF₂), zirconium oxide (ZrO₂), or the like is employed. Both the IR cut coating and the AR coating is formed on the base material by the vapor deposition. In addition, these coatings may be formed by the ion-assisted sputter.

Because the glass is used as the base material, the optical filter 5 can suppress the transmission of the ultraviolet rays. In contrast, a resin may be used as the base material. In this case, for example, the similar coating may be applied to the base material formed of PET (polyethylene terephthalate), or the like or films having a different refractive index respectively may be stacked. Since the resin used as the base material is not the fragile material unlike the glass and is difficult to break, the handling in an assembling operation can be facilitated.

Accordingly, when the automatic assembling is applied, a flexibility in selecting the handler can be broadened. Also, when the films are stacked, the biaxial orientation is applied to the resultant film to constitute a thin film after the films are stacked on the base material. Thus, it is feasible to get a thin film.

In the present embodiment, the optical filter 5 is constructed to suppress the transmission of the light except the visible light region. In this case, the optical filter can be modified to transmit the near-infrared rays for the purpose of night vision. The optical filter 5 is arranged over the opening portion 9 in the stepped portion 8A, and is secured to the plate-like member 8 by a ultraviolet curable and thermosetting adhesive 11 to cover the opening portion 9. It will be described that the optical filter 5 is positioned automatically at a time of adhering.

In the present embodiment, the plate-like member 8 is formed of a nonmagnetic stainless steel (SUS304, or the like) having a thickness of 0.2 mm, and the rectangular stepped portion 8A is formed in a center portion of the plate-like member 8 by the half die cutting using the press working. The almost rectangular opening portion 9 is provided in a center portion of the stepped portion 8A by the punching. The half die cutting of the stepped portion 8A and the opening portion 9 is carried out by the progressive press working, and mutual positional relationship can be set with good accuracy. A linear outer and inner wall surfaces 8a, 8b are provided in the stepped portion 8A, and the optical filter 5 and the wiring substrate 7, on which the semiconductor image pickup element 6 is mounted, can be positioned mutually with good precision. Since the stepped portion 8A is worked by the half die cutting, a precision that the normal drawing process cannot give can be realized. Also, since the linear portions can be provided by the outer and inner wall surfaces 8a, 8b, a positional precision can be improved easily.

In this case, in addition to the stainless, nickel silver containing nickel as a main component or the like can be employed as the plate-like member 8. Because the nickel silver is employed, a shielding property against a high-frequency electromagnetic wave can be improved. Thus, the EMI (Electromagnetic Interference: unwanted emissions) characteristic can be improved and a reduction of a receiving sensitivity when used in a cellular phone can be prevented.

Also, aluminum can be used as the plate-like member 8. In this case, there is such an advantage that a reduction in weight can be attained because of its low density. In the mobile terminal device such as a cellular phone, or the like, an improvement in portability and convenience in use is aimed at depending on how a weight of the device should be reduced, and a weight reduction in unit of 1 gr becomes important.

The wiring substrate 7 whose base material is formed of FR5 and has a thickness of 0.15 mm and whose copper foil is ½ Oz (18 μm) is employed. A hole 7b that can be fitted in the outer wall surface 8a, which is provided in the stepped portion 8A of the plate-like member 8, is provided in the wiring substrate 7 such that this hole 7b is positioned with respect to the plate-like member 8. Conductive patterns 7a are provided on a surface of the wiring substrate 7. The conductive patterns 7a are flip-chip mounted on bumps 21 by the connection method that is called SBB (Stud Bump Bonding), BGA (Ball Grid Array), or the like. The bumps 21 are formed of gold on connection pads 6a provided on the surface of the semiconductor image pickup element 6. In the SBB, a conductive adhesive such as an Ag paste, or the like is used as the conductive material adhered to the top end of the bump. In order to mount the semiconductor image pickup element 6 in a desired position upon mounting, first recognition marks (not shown) attached to the semiconductor image pickup element 6 are recognized, and a chucking is done. Then, the wiring substrate 7 is positioned on a basis of the similar recognition marks (not shown) that are provided on the wiring substrate 7, whereby the semiconductor image pickup element 6 is mounted on the wiring substrate 7. By doing so, a center of available pixels of the semiconductor image pickup element 6 can be positioned in a desired position on a basis of the plate-like member 8.

The wirings of the wiring substrate 7 are led to the outside via an FPC (flexible printed board) 15. A power supply, control signals, output signals, etc. are transmitted/received to/from a main body such as a mobile terminal device, or the like via the FPC 15.

As the semiconductor image pickup element 6, for example, a CCD called a ¼ inch UXGA type whose pixel number is about two millions or a CMOS is employed. As described above, the reason why the semiconductor image pickup element 6 is flip-chip mounted on the wiring substrate 7 is that no package should be used in mounting to implement the slimming down of the image pickup device. The semiconductor image pickup element 6 is adhered and sealed with a sealing agent 20 after the flip-chip mounting is done. In this case, the wiring substrate 7 may be formed of the FPC, or the FPC 15 and the wiring substrate 7 may be formed of one FPC. A reference 16 denotes a connector that is connected to the mobile terminal device. Here, the semiconductor image pickup device may be surface-mounted on the wiring substrate not to use the flip-chip mounting, and then may be wire-bonded to the pads that are formed on a surface on the side that opposes to the light receiving face of the image pickup device substrate. In this case, the bonding surface side of the semiconductor image pickup device as well as the wires must be sealed with a resin.

Next, the lens will be explained hereunder. The lens 2 being built in the lens holder 3 consists of two sheets of aspherical lenses (referred simply to as “lenses” hereinafter) 2a, 2b having a different optical characteristic respectively, and is fitted such that a predetermined positional relationship can be held. A PPA (Polyphthalamide) resin, or the like is used as the lens holder 3, and colored in black to prevent the transmission of light from the outside. Screws 3b, 4b that are screwed mutually are formed on the outer periphery of the lens holder 3 and the inside of the base 4 arranged outside the lens holder respectively. A position of the optical axis direction can be adjusted with respect to the base 4 by rotating the lens holder 3. Also, a contact surface 4a that is brought into contact with the plate-like member 8 is provided to a lower surface of the base 4. A boss (not shown) as a positioning means on a basis of the optical axis of the lens 2 is provided to the contact surface 4a, and can be fitted into a hole (not shown) provided to the plate-like member 8. The optical axis of the lens can be positioned with respect to the plate-like member 8 by the boss and the hole.

The lens 2 is formed of a resin material that satisfies necessary optical characteristics such as a transmittance, a refractive index, and the like. In the present embodiment, a so-called pan focus, which can form an image of the subject located beyond a predetermined distance, can be realized by using the product name “ZEONEX®” manufactured by Nippon Zeon Co., Ltd. More concretely, the lens 2 is designed to bring the subject located beyond about 30 cm into focus. However, material, structure, and characteristic of the lens 2 are not limited to those in the present embodiment, and can be varied appropriately according to the application, or the like. Also, the lens equipped with a macro changing function or an AF (Auto Focus) function can be employed.

Next, the semiconductor image pickup element 6, the wiring substrate 7, and the sealing agent 20 will be explained hereunder. As well known, the semiconductor image pickup element 6 is formed by the semiconductor process using a silicon single crystal as a starting material, and has pads to which the light receiving portion and the peripheral circuits are connected in its center portion. The light receiving portion has a dimension of about 2.7×3.6 mm by using Bayer alignment of a square pixel of 2.25 μm, and. The peripheral circuits containing OB (Optical Block) block, ADC, TG (Timing Generator), and the like are provided around the light receiving portion in the form of so-called one-chip sensor, and an outer shape is about 4.9×6.5 mm. The semiconductor image pickup element 6 is mounted on the wiring substrate 7 by the SBB, and the periphery is sealed/adhered by the sealing agent 20. The sealing agent 20 is the epoxy-based adhesive in which an initiator that can be cured by the ultraviolet rays and the heat is mixed, and a viscosity, an initiator, and the like are adjusted under various conditions. The semiconductor image pickup element 6 is mounted on the wiring substrate 7 by the SBB in a state that the lens holder 3 is not fitted. The sealing agent 20 is coated around the semiconductor image pickup element 6, and the ultraviolet rays are illuminated through the opening portion 9 from the top. Accordingly, the adhesive starts to cure from the periphery of the opening portion 9. Therefore, the projection of the adhesive into the opening portion 9 can be prevented and the image never falls into eclipse. After this, the adhesive is thermally cured at a temperature of about 125° C.

Next, the positioning of the optical filter 5 will be explained hereunder. A recess that is slightly larger than an outer shape of the optical filter 5 is formed on the inside of the stepped portion 8A of the plate-like member 8 by the half die cutting. The wall 8b corresponding to the outer shape of the optical filter 5 and a plane surface 8c corresponding to the lower surface of the optical filter 5 are simultaneously formed. According to the half die cutting, a depth of this recess is half of the plate thickness, i.e., 0.1 mm. Thus, because a thickness of the optical filter 5 is 0.15 mm, the optical filter 5 is protruded slightly by 0.05 mm from the upper surface of the plate-like member 8. Here, if a thickness of the plate-like member 8 is assumed as T1, a depth of this recess after the half die cutting is given by 0.5*T1. Meanwhile, if a thickness of the optical filter 5 is assumed as T2, the condition under which the optical filter 5 protrudes from the recess is given by Inequality 1.

T1<2*T2 (Inequality 1)

When the optical filter 5 becomes lower than the recess, such a situation may be considered that the adhesive 11 flows into the upper surface of the optical filter 5. Normally a refractive index of the adhesive is larger than 1. Therefore, the outflow of the adhesive into the image pickup available range is not preferable because an optical length given by the optical filter 5 is prolonged and a degradation of picture quality is brought out. In this case, when the adhesive does not flow into the inside of the opening portion 9, above Inequality 1 must not always be satisfied and can be varied adequately.

In the present embodiment, an interval between the outer shape of the optical filter 5 and the corresponding wall 8b is set to about 0.07 mm. In securing the optical filter 5 to the plate-like member 8, the optical filter 5 is inserted into the recess of the plate-like member 8, and then the adhesive 11 is coated on the periphery by the dispenser. As the adhesive 11, a UV-curable and thermosetting epoxy-based adhesive is employed. As the curing conditions, the adhesive is temporarily cured by the UV illumination and then is fully cured at 120° C. The adhesive 11 is liquid immediately after the coating. Therefore, a meniscus shape is formed between the optical filter 5 and the wall 8b of the recess. Accordingly, the optical filter 5 can be self-aligned in an almost center of the recess by the meniscus produced by a surface tension of the adhesive 11. As a result, this surface tension acts such that a clearance between the outer shape of the optical filter 5 and the corresponding wall 8b becomes substantially uniform, and thus the positioning of the optical filter 5 can be made with good precision not to use a particular jig.

In this manner, a center of the available pixels of the semiconductor image pickup element 6 and the optical axis of the lens can be positioned in a desired position on a basis of the plate-like member 8. Also, as apparent from the above explanation, the wiring substrate 7 and the optical filter 5 can be arranged by using the outer side and the inner side of the stepped portion 8A to overlap with each other in the optical axis direction. Therefore, such arrangement is effective in slimming down the image pickup device. In the present embodiment, a thickness can be reduced by an overlapped thickness between the optical filter 5 and the plate-like member 8 in the optical axis direction, i.e., 0.1 mm (a depth of the half die cutting).

In other words, in the image pickup device having the same height, thicknesses of the wiring substrate 7, the optical filter 5, and the plate-like member 8 can be increased much more, and a strength can be enhanced, and thus the characteristic against a drop impact, and the like can be improved. In particular, when the image pickup device is used in the cellular phone application, an improvement of a withstanding strength against a drop impact, and the like is needed. In such event, as described above, a strength can be improved and reliability can be improved.

### Embodiment 2

Next, Embodiment 2 of the present invention will be explained hereunder. In Embodiment 2, as shown in FIG. 5, the case where a recess portion 18A of the plate-like member (plate-like holding member) 18 is formed by the etching is explained. In this case, since the recess portion 18A is processed by the etching, no mechanical stress is applied to the plate-like holding member 18. Therefore, a precision of flatness can be improved.

Also, in the case of the press working, a level difference of the optical filter 5 and a level difference of the wiring substrate 7 are still kept. In contrast, in the case of shape process by the etching, a level difference of the optical filter 5 and a level difference of the wiring substrate 7 can be decided in magnitude freely, and a flexibility of design is enhanced. Further, a fine uneven surface is formed on the surface that is processed by the etching. This fine unevenness acts as an increase of a surface area when the optical filter 5, and the like are adhered/secured. An increase of the surface area can improve an adhesive property, and can enhance a adhesive strength. Accordingly, improvement of quality can be attained. The whole structure can be formed by the etching process. In this case, frames like the lead frames are shaped by the press working, and then only the stepped portion are formed by the etching process using a mask formed on both surfaces. As a result, the plate-like body can be formed extremely easily with good workability and with high dimensional precision.

Also, a fine uneven surface formed on the end surface of the opening portion 9 scatters a light. Accordingly, the ghost produced by a reflection at the end surface can be reduced. This corresponds to a situation that a matte coating is applied to the end surface to prevent a reflection. This can reduce the noise generated by the light transmitted through the back surface even when an image pickup element chip is slimmed down, and is effective particularly. According to such matte coating for reflection prevention, there is a possibility that a coating film is deteriorated due to an environmental change, a vibration impact, etc. to produce minutes cracks, etc., and then acts as the dusts to degrade a picture quality when the crack comes off, and the like. In contrast, since the base material never comes off from the fine unevenness produced by the etching, production of the dusts can be prevented and as a result the image pickup device of high quality can be realized.

### Embodiment 3

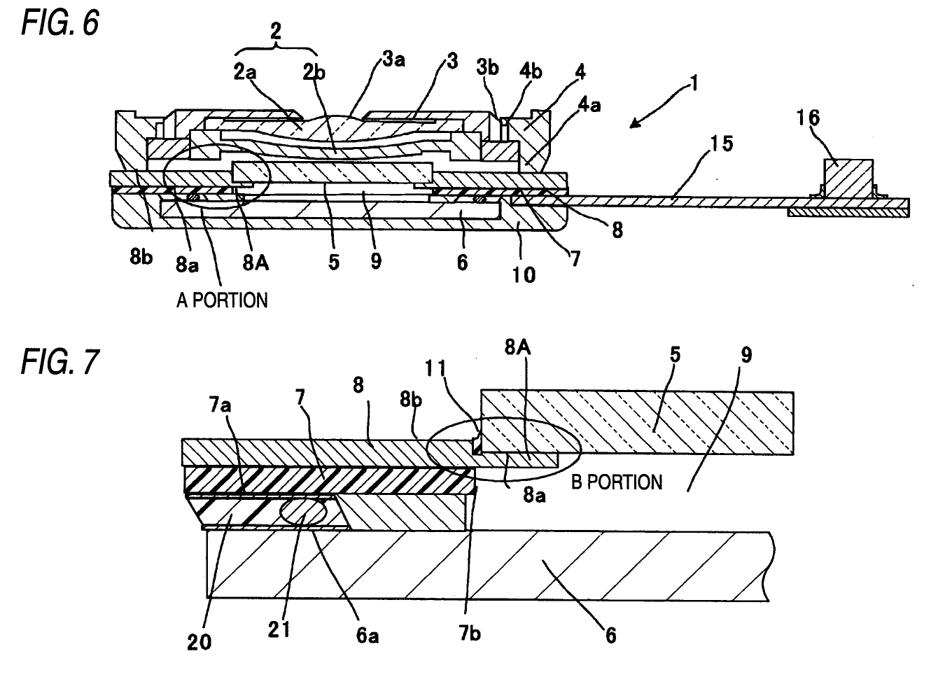

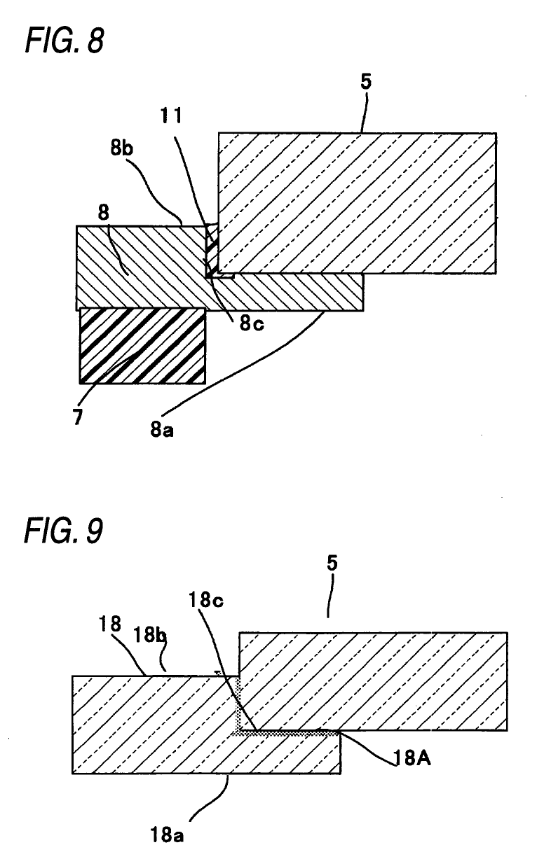

Next, Embodiment 3 of the present invention will be explained hereunder. A pertinent perspective view of the image pickup device of Embodiment 3 of the present invention is similar to that shown in above Embodiment 1. FIG. 6 is a sectional view taken along an X-X line in an image pickup device of Embodiment 3 of the present invention, FIG. 7 is an enlarged sectional view of an A portion of the image pickup device in FIG. 6, and FIG. 8 is an enlarged sectional view of a B portion of the image pickup: device in FIG. 7.

FIG. 1 is a perspective view showing a pertinent portion of the image pickup device 1. The image pickup device 1 has the lens holder 3 having the diaphragm 3a in its center portion on the subject side (upper side in FIG. 1), and the base 4 for holding the lens holder 3 to move in the optical axis. The lens 2 is adhered/secured to the inside of the lens holder 3. The lens 2 is positioned by the positioning means (not shown) via the base 4, and is adhered/secured to the plate-like member 8. The optical filter 5 and the semiconductor image pickup element 6 as the imaging device are fitted to the plate-like member 8 respectively. The image pickup device 1 is constructed such that a light from a subject passes through the diaphragm 3a and is converged by the lens 2, then the transmission of unnecessary infrared lights is limited by the optical filter 5, and then the resultant light is subjected to the photoelectric conversion by the semiconductor image pickup element 6 and is picked up as a desired electric signal.

As shown in FIG. 6, the image pickup device of the present invention includes the opening portion 9, has the recess portion 8A around the opening portion 9 on the first surface 8b, and is equipped with the plate-like member 8 whose second surface 8a opposing to the first surface 8b is formed flat, the optical filter 5 positioned/secured to the recess portion 8A formed on the first surface 8b to cover the opening portion 9, the wiring substrate 7 having the opening corresponding to the opening portion 9 in the plate-like member 8 and arranged on the second surface 8a of the plate-like member 8, and the semiconductor image pickup element 6 mounted on the wiring substrate 7. This wiring substrate 7 is positioned on the outside of the optical filter 5, and is arranged to surround its outer periphery when viewed from the top.

A configuration of the image pickup device 1 will be explained in more detail with reference to FIG. 6 to FIG. 8 hereunder. The recess portion 8A is provided to the center portion of the plate-like member 8, and the opening portion 9 is formed in its center portion. The opening portion 9 is formed like the rectangle having roughly a ratio of 3:4 to correspond to the shooting area of the semiconductor image pickup element 6. The optical filter 5 is adhered/secured to the inside of the recess portion 8A to cover the opening portion 9. The wiring substrate 7 is arranged on the outside to surround the optical filter 5, and the semiconductor image-pickup element 6 is flip-chip mounted on the wiring substrate 7. Also, the lens 2 is positioned by the boss (not shown), or the like, and is fitted to the plate-like member 8 via the base 4.

In the optical filter 5, the IR (Infra Red) cut coating is applied to one surface of the base material that is made of glass of 0.15 mm thick. The AR (Anti Reflection) coating for reflection prevention may be applied to the other surface if necessary. A coefficient of thermal expansion is about 7×10⁻⁶/° C. As the IR cut coating, for example, the dielectric film formed of silicon dioxide (SiO₂), titanium oxide (TiO₂), or the like and having a film thickness of almost several tens nm is stacked in several tens layers. The IR cut coating provides the spectral characteristic whose half-width wavelength is about 650 nm and in which the transmission of the light having the longer wavelength than this wavelength is sufficiently suppressed. As the AR coating for reflection prevention, for example, aluminum oxide (Al₂O₃), magnesium fluoride (MgF₂), zirconium oxide (ZrO₂), or the like is employed. Both the IR cut coating and the AR coating is formed on the base material by the vapor deposition. In addition, these coatings may be formed by the ion-assisted sputter.

Because the glass is used as the base material, the optical filter 5 can suppress the transmission of the ultraviolet rays. In contrast, the resin may be used as the base material. In this case, for example, the similar coating may be applied to the base material formed of PET (polyethylene terephthalate), or the like or films having a different refractive index respectively may be stacked. Since the resin used as the base material is not the fragile material unlike the glass and is difficult to break, the handling in the assembling operation can be facilitated.

Accordingly, when the automatic assembling is applied, a flexibility in selecting the handler can be broadened. Also, when the films are stacked, the biaxial orientation is applied to the resultant film to constitute a thin film after the films are stacked on the base material. Thus, it is feasible to get a thin film.

In the present embodiment, the optical filter 5 is constructed to suppress the transmission of the light except the visible light region. In this case, the optical filter can be modified to transmit the near-infrared rays for the purpose of night vision. The optical filter 5 is arranged in the recess portion 8A, and is secured to the plate-like member 8 by the ultraviolet curable and thermosetting adhesive 11 to cover the opening portion 9. It will be described that the optical filter 5 is positioned automatically at a time of adhering.

In the present embodiment, the plate-like member 8 is formed of a nonmagnetic stainless steel (SUS304, or the like) having a thickness of 0.2 mm, and the rectangular recess portion 8A is formed by the press working after a part of the plate-like member 8 is reduced in thickness. The almost rectangular opening portion 9 is provided in a center portion of the recess portion 8A by the punching. A pilot hole called the thickness removing process is opened, then a thickness of the plate-like member 8 is partially reduced, and then the recess portion 8A and the opening portion 9 are formed by the blanking using the progressive press working, whereby mutual positional relationship can be set with good accuracy. The second surface 8a as the lower surface of the plate-like member 8 is made flat and the optical filter 5 is provided on the first surface 8b, and the optical filter 5 and the wiring substrate 7, on which the semiconductor image pickup element 6 is mounted, can be positioned mutually with good precision. As described above, because the recess portion 8A is formed by the thickness removing process, a high precision that cannot be obtained by the normal drawing process can be obtained. Also, because the wiring substrate 7 is fitted on the second surface 8a of the plate-like member as the flat surface, nor distortion is caused, the assembling workability is good, and a positioning precision is high. Also, since the semiconductor image pickup element 6 is flip-chip mounted on the wiring substrate 7, the slimming down can be attained much more.

In this case, in addition to the stainless, nickel silver containing nickel as a main component, or the like can be employed as the plate-like member 8. Because the nickel silver is employed, a shielding property against a high-frequency electromagnetic wave can be improved. Thus, the EMI (Electromagnetic Interference: unwanted emissions) characteristic can be improved and a reduction of a receiving sensitivity when used in a cellular phone can be prevented.

Also, aluminum can be used as the plate-like member 8. In this case, there is such an advantage that a reduction in weight can be attained because of its low density. In the mobile terminal device such as a cellular phone, or the like, an improvement in portability and convenience in use is aimed at depending on how a weight of the device should be reduced, and a weight reduction in unit of 1 gr becomes important.

The wiring substrate 7 whose base material is formed of FR5 and has a thickness of 0.15 mm and whose copper foil is ½ Oz (18 μm) is employed. A positioning hole (not shown) is provided in the wiring substrate 7 such that this hole 7b is positioned with respect to the plate-like member 8. Conductive patterns 7a are provided on a surface of the wiring substrate 7. The conductive patterns 7a are flip-chip mounted on bumps 21 by the connection method that is called SBB (Stud Bump Bonding), BGA (Ball Grid Array), or the like. The bumps 21 are formed of gold on connection pads 6a provided on the surface of the semiconductor image pickup element 6. In the SBB, a conductive adhesive such as an Ag paste, or the like is used as the conductive material adhered to the top end of the bump. In order to mount the semiconductor image pickup element 6 in a desired position upon mounting, first recognition marks (not shown) attached to the semiconductor image pickup element 6 are recognized, and a chucking is done. Then, the wiring substrate 7 is positioned on a basis of the similar recognition marks (not shown) that are provided on the wiring substrate 7, whereby the semiconductor image pickup element 6 is mounted on the wiring substrate 7. By doing so, a center of available pixels of the semiconductor image pickup element 6 can be positioned in a desired position on a basis of the plate-like member 8.

The wirings of the wiring substrate 7 are led to the outside via an FPC (flexible printed board) 15. A power supply, control signals, output signals, etc. are transmitted/received to/from a main body such as a mobile terminal device, or the like via the FPC 15.

As the semiconductor image pickup element 6, for example, a CCD called a ¼ inch UXGA type whose pixel number is about two millions or a CMOS is employed. As described above, the reason why the semiconductor image pickup element 6 is flip-chip mounted on the wiring substrate 7 is that no package should be used in mounting to implement the slimming down of the image pickup device. The semiconductor image pickup element 6 is adhered and sealed with a sealing agent 20 after the flip-chip mounting is done. In this case, the wiring substrate 7 may be formed of the FPC, or the FPC 15 and the wiring substrate 7 may be formed of one FPC. A reference 16 denotes a connector that is connected to the mobile terminal device. Here, the semiconductor image pickup device may be surface-mounted on the wiring substrate not to use the flip-chip mounting, and then may be wire-bonded to the pads that are formed on a surface on the side that opposes to the light receiving face of the image pickup device substrate. In this case, the bonding surface side of the semiconductor image pickup device as well as the wires must be sealed with a resin.

Next, the lens will be explained hereunder. The lens 2 being built in the lens holder 3 consists of two sheets of aspherical lenses (referred simply to as “lenses” hereinafter) 2a, 2b having a different optical characteristic respectively, and is fitted such that a predetermined positional relationship can be held. A PPA (Polyphthalamide) resin, or the like is used as the lens holder 3, and colored in black to prevent the transmission of light from the outside. Screws 3b, 4b that are screwed mutually are formed on the outer periphery of the lens holder 3 and the inside of the base 4 arranged outside the lens holder respectively. A position of the optical axis direction can be adjusted with respect to the base 4 by rotating the lens holder 3. Also, a contact surface 4a that is brought into contact with the plate-like member 8 is provided to a lower surface of the base 4. A boss (not shown) as a positioning means on a basis of the optical axis of the lens 2 is provided to the contact surface 4a, and can be fitted into a hole (not shown) provided to the plate-like member 8. The optical axis of the lens can be positioned with respect to the plate-like member 8 by the boss and the hole.

The lens 2 is formed of a resin material that satisfies necessary optical characteristics such as a transmittance, a refractive indexᵢ and the like. In the present embodiment, a so-called pan focus, which can form an image of the subject located beyond a predetermined distance, can be realized by using the product name “ZEONEX®” manufactured by Nippon Zeon Co., Ltd. More concretely, the lens 2 is designed to bring the subject located beyond about 30 cm into focus. However, material, structure, and characteristic of the lens 2 are not limited to those in the present embodiment, and can be varied appropriately according to the application, or the like. Also, the lens equipped with a macro changing function or an AF (Auto Focus) function can be employed.

Next, the semiconductor image pickup element 6, the wiring substrate 7, and the sealing agent 20 will be explained hereunder. As well known, the semiconductor image pickup element 6 is formed by the semiconductor process using a silicon single crystal as a starting material, and has pads to which the light receiving portion and the peripheral circuits are connected in its center portion. The light receiving portion has a dimension of about 2.7×3.6 mm by using Bayer alignment of a square pixel of 2.25 μm, and. The peripheral circuits containing OB (Optical Block) block, ADC, TG (Timing Generator), and the like are provided around the light receiving portion in the form of so-called one-chip sensor, and an outer shape is about 4.9×6.5 mm. The semiconductor image pickup element 6 is mounted on the wiring substrate 7 by the SBB, and the periphery is sealed/adhered by the sealing agent 20. The sealing agent 20 is the epoxy-based adhesive in which an initiator that can be cured by the ultraviolet rays and the heat is mixed, and a viscosity, an initiator, and the like are adjusted under various conditions. The semiconductor image pickup element 6 is mounted on the wiring substrate 7 by the SBB in a state that the lens holder 3 is not fitted. The sealing agent 20 is coated around the semiconductor image pickup element 6, and the ultraviolet rays are illuminated through the opening portion 9 from the top. Accordingly, the adhesive starts to cure from the periphery of the opening portion 9. Therefore, the projection of the adhesive into the opening portion 9 can be prevented and the image never falls into eclipse. After this, the adhesive is thermally cured at a temperature of about 125° C.

Next, the positioning of the optical filter 5 will be explained hereunder. A recess that is slightly larger than an outer shape of the optical filter 5 is formed on the inside of the recess portion 8A of the plate-like member 8 by applying the and then the punching. The wall 8b corresponding to the outer shape of the optical filter 5 and the plane surface 8c corresponding to the lower surface of the optical filter 5 are formed.

When the upper surface of the optical filter 5 becomes lower than the recess portion, such a situation may be considered that the adhesive 11 flows into the upper surface of the optical filter 5. Normally a refractive index of the adhesive is larger than 1. Therefore, the outflow of the adhesive into the image pickup available range is not preferable because an optical length given by the optical filter 5 is prolonged and a degradation of picture quality is brought out.

In the present embodiment, an interval between the outer shape of the optical filter 5 and the corresponding wall 8c is set to about 0.07 mm. In securing the optical filter 5 to the plate-like member 8, the optical filter 5 is inserted into the recess portion 8A of the plate-like member 8, and then the adhesive 11 is coated on the periphery by the dispenser. As the adhesive 11, a UV-curable and thermosetting epoxy-based adhesive is employed. As the curing conditions, the adhesive is temporarily cured by the UV illumination and then is fully cured at 120° C. The adhesive 11 is liquid immediately after the coating. Therefore, a meniscus shape is formed between the optical filter 5 and the wall 8b of the recess. Accordingly, the optical filter 5 can be self-aligned in an almost center of the recess portion 8A by the meniscus produced by a surface tension of the adhesive 11. As a result, this surface tension acts such that a clearance between the outer shape of the optical filter 5 and the corresponding wall 8c becomes substantially uniform, and thus the positioning of the optical filter 5 can be made with good precision not to use a particular jig.

In this manner, a center of the available pixels of the semiconductor image pickup element 6 and the optical axis of the lens can be positioned in a desired position on a basis of the plate-like member 8. The slimming down can be achieved by the arrangement using the recess portion. In other words, in the image pickup device having the same height, thicknesses of the wiring substrate 7, the optical filter 5, and the plate-like member 8 can be increased much more, and a strength can be enhanced, and thus the characteristic against a drop impact, and the like can be improved. In particular, when the image pickup device is used in the cellular phone application, an improvement of a withstanding strength against a drop impact, and the like is needed. In such event, as described above, a strength can be improved and reliability can be improved.

In this case, a positional precision of the optical filter is important. The reason will be explained as follows. The lens is designed such that a light emitted from the lens is spread toward the image pickup device. Precisely the lens is constructed such that a light is emitted from an emergent eye position. Here, a dimension obtained by adding an adhered portion to the opening portion of the plate-like member is required of a size of the optical filter.

Also, in manufacturing the optical filter, there is a limitation to cause a work size (plate member prior to the splitting) to grow a uniform film formation in the vapor deposition equipment. The work size is almost 70 mm, and it is said that the work size can be set a little larger in the thick glass.

When processing the work from the work size to a product, the method of dividing the work by the dicing using a diamond blade is employed. That is, a cost is decided in response to the number of the products picked up from the work size. For this reason, a cost can be reduced by minimizing a size of the optical filter containing the adhered area.

In contrast, when the large optical filter is employed, the optical filter and the image pickup device overlap with each other when viewed from the top. A center portion of the image pickup device is called the available imaging area, and actually a light is converted into an electric signal by the phototransistor there. The peripheral circuits, and the like are provided on the outside of this available area, and wiring electrodes are provided on the further outside. When the wiring portions and the optical filter overlap mutually, mutual interference occurs between them to arrange them in the thickness direction (optical axis direction) respectively. Therefore, a thickness is increased.

From the above reason, it is desirable that a small optical filter should be employed to realize the slimming down and a cost reduction. Therefore, a positioning precision is needed to cover the available range of rays without fail. In fact, an outer dimension tolerance of the optical filter used in the present embodiment is set to ±0.05 mm. A tolerance of the recess into which the optical filter is inserted is set to ±0.02 mm.

Also, when a size of the optical filter is increased, an inclination of the optical filter to the optical axis occurs depending on a flatness of the fitting surface. An incident angle is slightly changed when the optical filter is inclined. In particular, since the reflection type filter is formed of a multi-layered film, a half-width wavelength (λd, i.e., a cutoff frequency fc in the electric field) is shortened when an incident angle is increased. Accordingly, a change is caused in color reproducibility. In order to prevent this, it is advantageous that a size of the optical filter should be reduced as small as possible.

Also, the optical filter gives a mechanical strength to the image pickup device as the structural body in addition to the optical function. Also, the optical filter has an influence on a mounting precision. A Young's modulus of the glass as the base material is almost half of a silicon, and is high rather than a resin, and the like. Therefore, the optical filter is constructed to give a strength as the structural body. As a result, a positional precision becomes important to enhance a mechanical strength in the slimming down.

### Embodiment 4

Next, Embodiment 4 of the present invention will be explained hereunder. In Embodiment 4, as shown a pertinent enlarged view in FIG. 9, the case where the recess portion 18A of a plate-like member 18 is processed by the etching is illustrated. In this case, since the recess portion is formed by the etching, no mechanical stress is applied to the plate-like member 18 and therefore a precision of the flatness can be improved. Like Embodiment 1, the image pickup device of the present embodiment includes the opening portion 9, has the recess portion 18A around the opening portion 9 on a first surface 18b, and is equipped with the plate-like member 18 whose second surface 18a opposing to the first surface 18b is formed flat, the optical filter 5 positioned/secured to the recess portion 18A formed on the first surface 18b to cover the opening portion 9, the wiring substrate 7 having the opening corresponding to the opening portion 9 in the plate-like member 18 and arranged on the second surface 18a of the plate-like member 18, and the semiconductor image pickup element 6 mounted on the wiring substrate 7. Also, a recess portion in the first surface 18a is constructed by a surface 18c that has an unevenness produced by the etching.

Also, when the shape is processed by the etching, a level difference of the optical filter 5 and a level difference of the lens 2b can be decided in magnitude freely in contrast to the case of the press working (thickness removing process), and a flexibility of design is also enhanced. Further, a fine uneven surface is formed on the surface that is processed by the etching. This fine unevenness acts as an increase of a surface area when the optical filter 5, and the like are adhered/secured. An increase of the surface area can improve an adhesive property, and can enhance a adhesive strength. Accordingly, improvement of quality can be attained. The whole structure can be formed by the etching process. In this case, frames like the lead frames are shaped by the press working, and then only the stepped portion are formed by the etching process using a mask formed on both surfaces. As a result, the plate-like body can be formed extremely easily with good workability and with high dimensional precision.

Also, a fine uneven surface formed on the end surface of the opening portion 9 scatters a light. Accordingly, the ghost produced by a reflection at the end surface can be reduced. This corresponds to a situation that a matte coating is applied to the end surface to prevent a reflection. This can reduce the noise generated by the light transmitted through the back surface even when an image pickup element chip is slimmed down, and is effective particularly. According to such matte coating for reflection prevention, there is a possibility that a coating film is deteriorated due to an environmental change, a vibration impact, etc. to produce minutes cracks, etc., and then acts as the dusts to degrade a picture quality when the crack comes off, and the like. In contrast, since the base material never comes off from the fine unevenness produced by the etching, production of the dusts can be prevented and as a result the image pickup device of high quality can be realized.

### Embodiment 5

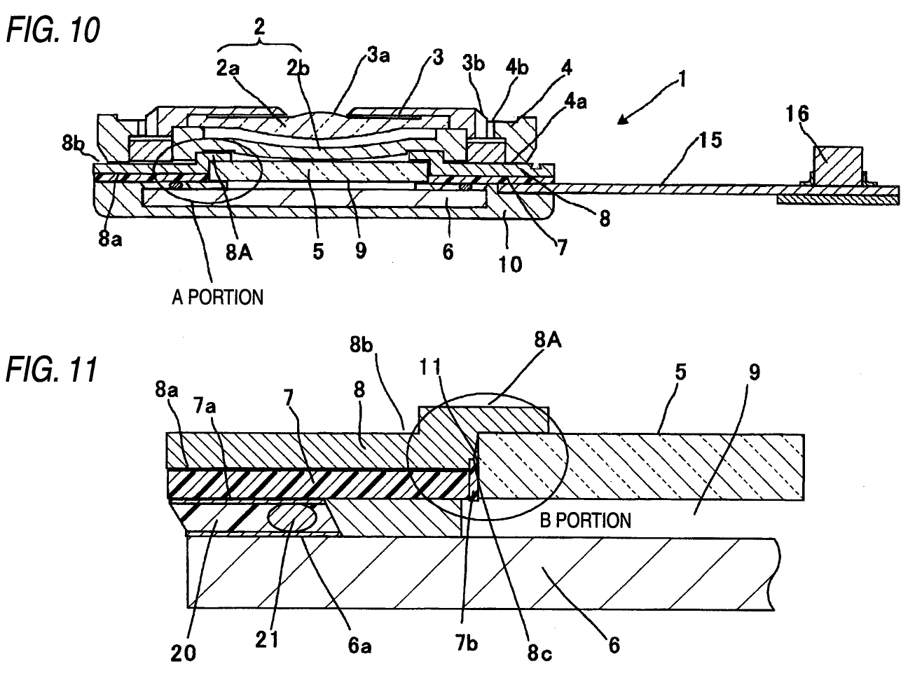

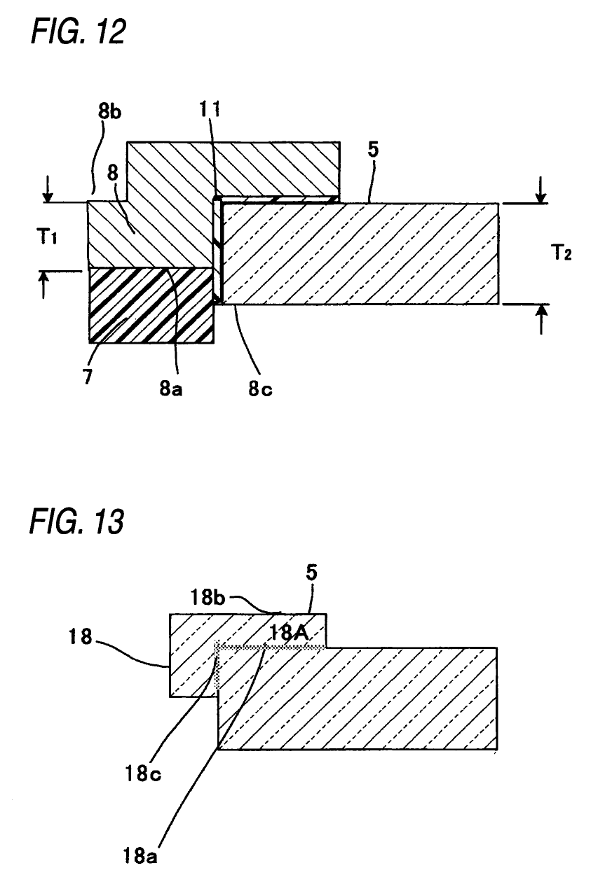

Next, Embodiment 5 of the present invention will be explained hereunder. FIG. 1 is a pertinent perspective view of the image pickup device of the present invention like Embodiment 1. FIG. 10 is a sectional view taken along an X-X line in an image pickup device of the present invention, FIG. 11 is an enlarged sectional view of an A portion of the image pickup device in FIG. 10, and FIG. 12 is an enlarged sectional view of a B portion of the image pickup device in FIG. 11.

FIG. 1 is a perspective view showing the pertinent portion of the image pickup device 1. The image pickup device 1 has the lens holder 3 having the diaphragm 3a in its center portion on the subject side (upper side in FIG. 1), and the base 4 for holding the lens holder 3 to move in the optical axis. The lens 2 is adhered/secured to the inside of the lens holder 3. The lens 2 is positioned by a positioning means (not shown) via the base 4, and is adhered/secured to a plate-like member 8. The optical filter 5 and the semiconductor image pickup element 6 as an imaging device are fitted to the plate-like member 8 respectively. The image pickup device 1 is constructed such that a light from the subject passes through the diaphragm 3a and is converged by the lens 2, then the transmission of unnecessary infrared lights is limited by the optical filter 5, and then a resultant light is subjected to a photoelectric conversion by the semiconductor image pickup element 6 and is picked up as the desired electric signal.

As shown in FIG. 10, the image pickup device of the present invention is characterized in that the optical filter 5 is fitted in the recess on the inside of the stepped portion 8A of the plate-like member 8, in which the stepped portion having an opening in its center is provided, to cover the opening portion 9, the wiring substrate 7 having the hole corresponding to the optical filter 5 is fitted on the second surface 8a of the plate-like member 8, the semiconductor image pickup element 6 is mounted on the wiring substrate 7, and the lens 2 is fitted to the first surface 8b of the plate-like member 8 such that the opening portion 9 and the lens 2 are arranged to overlap with each other in the optical axis direction.

Next, a configuration of the image pickup device 1 will be explained in detail with reference to FIG. 10 to FIG. 12 hereunder. The stepped portion 8A is provided to the center portion of the plate-like member 8, and the opening portion 9 is formed in its center portion. The opening portion 9 is formed like the rectangle having roughly a ratio of 3:4 to correspond to the shooting area of the semiconductor image pickup element 6. The optical filter 5 is adhered/secured to the inside of the stepped portion 8A to cover the opening portion 9. The wiring substrate 7 is arranged on the outside to surround the periphery of the optical filter 5, and the semiconductor image pickup element 6 is flip-chip mounted on the wiring substrate 7. Also, the lens 2 is positioned by the boss (not shown), or the like, and is fitted to the plate-like member 8 via the base 4.

In the optical filter 5, an IR (Infra Red) cut coating is applied to one surface of a base material that is made of glass of 0.15 mm thick. An AR (Anti Reflection) coating for reflection prevention may be applied to the other surface if necessary. A coefficient of thermal expansion is about 7×10⁻⁶/° C. As the IR cut coating, for example, a dielectric film formed of silicon dioxide (SiO₂), titanium oxide (TiO₂), or the like and having a film thickness of almost several tens nm is stacked in several tens layers. The IR cut coating provides the spectral characteristic whose half-width wavelength is about 650 nm and in which a transmission of the light having the longer wavelength than this wavelength is sufficiently suppressed. As the AR coating for reflection prevention, for example, aluminum oxide (Al₂O₃), magnesium fluoride (MgF₂), zirconium oxide (ZrO₂), or the like is employed. Both the IR cut coating and the AR coating is formed on the base material by the vapor deposition. In addition, these coatings may be formed by the ion-assisted sputter.

Because the glass is used as the base material, the optical filter 5 can suppress the transmission of the ultraviolet rays. In contrast, a resin may be used as the base material. In this case, for example, the similar coating may be applied to the base material formed of PET (polyethylene terephthalate), or the like or films having a different refractive index respectively may be stacked. Since the resin used as the base material is not the fragile material unlike the glass and is difficult to break, the handling in an assembling operation can be facilitated.

Accordingly, when the automatic assembling is applied, a flexibility in selecting the handler can be broadened. Also, when the films are stacked, the biaxial orientation is applied to the resultant film to constitute a thin film after the films are stacked on the base material. Thus, it is feasible to get a thin film.

In the present embodiment, the optical filter 5 is constructed to suppress the transmission of the light except the visible light region. In this case, the optical filter can be modified to transmit the near-infrared rays for the purpose of night vision. The optical filter 5 is arranged over the opening portion 9 in the stepped portion 8A, and is secured to the plate-like member 8 by a ultraviolet curable and thermosetting adhesive 11 to cover the opening portion 9. It will be described that the optical filter 5 is positioned automatically at a time of adhering.

In the present embodiment, the plate-like member 8 is formed of a nonmagnetic stainless steel (SUS304, or the like) having a thickness of 0.2 mm, and the rectangular stepped portion 8A is formed in a center portion of the plate-like member 8 by the half die cutting using the press working. The almost rectangular opening portion 9 is provided in a center portion of the stepped portion 8A by the punching. The half die cutting of the stepped portion 8A and the opening portion 9 is carried out by the progressive press working, and mutual positional relationship can be set with good accuracy. The second surface 8a as the lower surface of the plate-like member 8 is made flat and the optical filter 5 is provided on the first surface 8b, and the optical filter 5 and the wiring substrate 7, on which the semiconductor image pickup element 6 is mounted, can be positioned mutually with good precision. Since the stepped portion 8A is worked by the half die cutting, a precision that the normal drawing process cannot give can be realized. Also, a thickness of the optical filter is 0.15 mm, and the optical filter is projected from the first surface by 0.05 mm. Since the wiring substrate 7 is positioned to surround the outer periphery of the optical filter 5 in this projected portion, the assembling workability is good and a positioning precision is high.

In this case, in addition to the stainless, nickel silver containing nickel as a main component, or the like can be employed as the plate-like member 8. Because the nickel silver is employed, a shielding property against a high-frequency electromagnetic wave can be improved. Thus, the EMI (Electromagnetic Interference: unwanted emissions) characteristic can be improved and a reduction of a receiving sensitivity when used in a cellular phone can be prevented.

Also, the aluminum can be used as the plate-like member 8. In this case, there is such an advantage that a reduction in weight can be attained because of its low density. In the mobile terminal device such as a cellular phone, or the like, an improvement in portability and convenience in use is aimed at depending on how a weight of the device should be reduced, and a weight reduction in unit of 1 gr becomes important.

The wiring substrate 7 whose base material is formed of FR5 and has a thickness of 0.15 mm and whose copper foil is ½ Oz (18 μm) is employed. The recess portion of the stepped portion 8A is formed by the half die cutting and a depth of the recess portion is 0.1 mm. When the optical filter 5 of 0.15 mm thick is mounted in this recess portion, this optical filter 5 protrudes downward from the second flat surface 8a of the plate-like member 8 by about 0.05 mm. Then, when the hole provided in the wiring substrate 7 is fitted in the protruded portion of the optical filter 5, the wiring substrate 7 can be positioned with respect to the plate-like member 8 via the optical filter 5 with good precision in the optical axis direction. Also, this overlap between the wiring substrate 7 and the optical filter 5 in the optical axis direction allows a reduction in thickness of the image pickup device. The conductive patterns 7a are flip-chip mounted on bumps 21 by the connection method that is called SBB (Stud Bump Bonding), BGA (Ball Grid Array), or the like. The bumps 21 are formed of gold on connection pads 6a provided on the surface of the semiconductor image pickup element 6. In the SBB, a conductive adhesive such as an Ag paste, or the like is used as the conductive material adhered to the top end of the bump. In order to mount the semiconductor image pickup element 6 in a desired position upon mounting, first recognition marks (not shown) attached to the semiconductor image pickup element 6 are recognized, and a chucking is done. Then, the wiring substrate 7 is positioned on a basis of the similar recognition marks (not shown) that are provided on the wiring substrate 7, whereby the semiconductor image pickup element 6 is mounted on the wiring substrate 7. By doing so, a center of available pixels of the semiconductor image pickup element 6 can be positioned in a desired position on a basis of the plate-like member 8.

The wirings of the wiring substrate 7 are led to the outside via an FPC (flexible printed board) 15. A power supply, control signals, output signals, etc. are transmitted/received to/from a main body such as a mobile terminal device, or the like via the FPC 15.

As the semiconductor image pickup element 6, for example, a CCD called a ¼ inch UXGA type whose pixel number is about two millions or a CMOS is employed. As described above, the reason why the semiconductor image pickup element 6 is flip-chip mounted on the wiring substrate 7 is that no package should be used in mounting to implement the slimming down of the image pickup device. The semiconductor image pickup element 6 is adhered and sealed with a sealing agent 20 after the flip-chip mounting is done. In this case, the wiring substrate 7 may be formed of the FPC, or the FPC 15 and the wiring substrate 7 may be formed of one FPC. Also, a connector 16 is fitted to the FPC 15 to attain the connection to the mobile terminal device. Here, the semiconductor image pickup device may be surface-mounted on the wiring substrate not to use the flip-chip mounting, and then may be wire-bonded to the pads that are formed on a surface on the side that opposes to the light receiving face of the image pickup device substrate. In this case, the bonding surface side of the semiconductor image pickup device as well as the Wires must be sealed with a resin.

Next, the lens will be explained hereunder. The lens 2 being built in the lens holder 3 consists of two sheets of aspherical lenses (referred simply to as “lenses” hereinafter) 2a, 2b having a different optical characteristic respectively, and is fitted such that a predetermined positional relationship can be held. A PPA (Polyphthalamide) resin, or the like is used as the lens holder 3, and colored in black to prevent the transmission of light from the outside. Screws 3b, 4b that are screwed mutually are formed on the outer periphery of the lens holder 3 and the inside of the base 4 arranged outside the lens holder respectively. A position of the optical axis direction can be adjusted with respect to the base 4 by rotating the lens holder 3. Also, a contact surface 4a that is brought into contact with the plate-like member 8 is provided to a lower surface of the base 4. A boss (not shown) as a positioning means on a basis of the optical axis of the lens 2 is provided to the contact surface 4a, and can be fitted into a hole (not shown) provided to the plate-like member 8. The optical axis of the lens can be positioned with respect to the plate-like member 8 by the boss and the hole.

The lens 2 is formed of a resin material that satisfies necessary optical characteristics such as a transmittance, a refractive index, and the like. In the present embodiment, a so-called pan focus, which can form an image of the subject located beyond a predetermined distance, can be realized by using the product name “ZEONEX®” manufactured by Nippon Zeon Co., Ltd. More concretely, the lens 2 is designed to bring the subject located beyond about 30 cm into focus. However, material, structure, and characteristic of the lens 2 are not limited to those in the present embodiment, and can be varied appropriately according to the application, or the like. Also, the lens equipped with a macro changing function or an AF (Auto Focus) function can be employed.

Next, the semiconductor image pickup element 6, the wiring substrate 7, and the sealing agent 20 will be explained hereunder. As well known, the semiconductor image pickup element 6 is formed by the semiconductor process using a silicon single crystal as a starting material, and has pads to which the light receiving portion and the peripheral circuits are connected in its center portion. The light receiving portion has a dimension of about 2.7×3.6 mm by using Bayer alignment of a square pixel of 2.25 μm, and. The peripheral circuits containing OB (Optical Block) block, ADC, TG (Timing Generator), and the like are provided around the light receiving portion in the form of so-called one-chip sensor, and an outer shape is about 4.9×6.5 mm. The semiconductor image pickup element 6 is mounted on the wiring substrate 7 by the SBB, and the periphery is sealed/adhered by the sealing agent 20. The sealing agent 20 is the epoxy-based adhesive in which an initiator that can be cured by the ultraviolet rays and the heat is mixed, and a viscosity, an initiator, and the like are adjusted under various conditions. The semiconductor image pickup element 6 is mounted on the wiring substrate 7 by the SBB in a state that the lens holder 3 is not fitted. The sealing agent 20 is coated around the semiconductor image pickup element 6, and the ultraviolet rays are illuminated through the opening portion 9 from the top. Accordingly, the adhesive starts to cure from the periphery of the opening portion 9. Therefore, the projection of the adhesive into the opening portion 9 can be prevented and the image never falls into eclipse. After this, the adhesive is thermally cured at a temperature of about 125° C.

Next, the positioning of the optical filter 5 will be explained hereunder. A recess that is slightly larger than an outer shape of the optical filter 5 is formed on the inside of the stepped portion 8A of the plate-like member 8 by the half die cutting. The wall corresponding to the outer shape of the optical filter 5 and a plane surface corresponding to the upper surface of the optical filter 5 are simultaneously formed. According to the half die cutting, a depth of this recess is half of the plate thickness, i.e., 0.1 mm. Thus, because a thickness of the optical filter 5 is 0.15 mm, the optical filter 5 is protruded slightly by 0.05 mm from the lower surface of the plate-like member 8. Here, if a thickness of the plate-like member 8 is assumed as T1, a depth of this recess after the half die cutting is given by 0.5*T1. Meanwhile, if a thickness of the optical filter 5 is assumed as T2, the condition under which the optical filter 5 protrudes from the recess is given by Inequality 1.

T1<2*T2 (Inequality-1)

When the optical filter 5 becomes lower than the recess, such a situation may be considered that the adhesive 11 flows into the upper surface of the optical filter 5. Normally a refractive index of the adhesive is larger than 1. Therefore, the outflow of the adhesive into the image pickup available range is not preferable because an optical length given by the optical filter 5 is prolonged and a degradation of picture quality is brought out. In this case, when the adhesive does not flow into the inside of the opening portion 9, above Inequality 1 must not always be satisfied and can be varied adequately.

In the present embodiment, an interval between the outer shape of the optical filter 5 and the corresponding wall 8c is set to about 0.07 mm. In securing the optical filter 5 to the plate-like member 8, the optical filter 5 is inserted into the recess of the plate-like member 8, and then the adhesive 11 is coated on the periphery by the dispenser. As the adhesive 11, a UV-curable and thermosetting epoxy-based adhesive is employed. As the curing conditions, the adhesive is temporarily cured by the UV illumination and then is fully cured at. 120° C. The adhesive 11 is liquid immediately after the coating. Therefore, a meniscus shape is formed between the optical filter 5 and the wall 8b of the recess. Accordingly, the optical filter 5 can be self-aligned in an almost center of the recess by the meniscus produced by a surface tension of the adhesive 11. As a result, this surface tension acts such that a clearance between the outer shape of the optical filter 5 and the corresponding wall 8b becomes substantially uniform, and thus the positioning of the optical filter 5 can be made with good precision not to use a particular jig.

In this manner, a center of the available pixels of the semiconductor image pickup element 6 and the optical axis of the lens can be positioned in a desired position on a basis of the plate-like member 8. Also, as apparent from the above explanation, the plate-like member 8 and the lens 2b can be arranged by using the outer side and the inner side of the stepped portion 8A to overlap with each other in the optical axis direction. Therefore, such arrangement is effective in slimming down the image pickup device. In the present embodiment, a thickness can be reduced by an overlapped thickness between the lens 2b and the plate-like member 8 in the optical axis direction, i.e., 0.1 mm (a depth of the half die cutting).

In other words, in the image pickup device having the same height, thicknesses of the wiring substrate 7, the optical filter 5, and the plate-like member 8 can be increased much more, and a strength can be enhanced, and thus the characteristic against a drop impact, and the like can be improved. In particular, when the image pickup device is used in the cellular phone application, an improvement of a withstanding strength against a drop impact, and the like is needed. In such event, as described above, a strength can be improved and reliability can be improved.

In this case, a positional precision of the optical filter is important. The reason will be explained as follows. The lens is designed such that a light emitted from the lens is spread toward the image pickup device. Precisely the lens is constructed such that a light is emitted from an emergent eye position. Here, a dimension obtained by adding an adhered portion to the opening portion of the plate-like member is required of a size of the optical filter.

Also, in manufacturing the optical filter, there is a limitation to cause a work size (plate member prior to the splitting) to grow a uniform film formation in the vapor deposition equipment. The work size is almost 70 mm, and it is said that the work size can be set a little larger in the thick glass.

When processing the work from the work size to a product, the method of dividing the work by the dicing using a diamond blade is employed. That is, a cost is decided in response to the number of the products picked up from the work size. For this reason, a cost can be reduced by minimizing a size of the optical filter containing the adhered area.

In contrast, when the large optical filter is employed, the optical filter and the image pickup device overlap with each other when viewed from the top. A center portion of the image pickup device is called the available imaging area, and actually a light is converted into an electric signal by the phototransistor there. The peripheral circuits, and the like are provided on the outside of this available area, and wiring electrodes are provided on the further outside. When the wiring portions and the optical filter overlap mutually, mutual interference occurs between them to arrange them in the thickness direction (optical axis direction) respectively. Therefore, a thickness is increased.

From the above reason, it is desirable that a small optical filter should be employed to realize the slimming down and a cost reduction. Therefore, a positioning precision is needed to cover the available range of rays without fail. In fact, an outer dimension tolerance of the optical filter used in the present embodiment is set to ±0.05 mm. A tolerance of the recess into which the optical filter is inserted is set to ±0.02 mm.

Also, when a size of the optical filter is increased, an inclination of the optical filter to the optical axis occurs depending on a flatness of the fitting surface. An incident angle is slightly changed when the optical filter is inclined. In particular, since the reflection type filter is formed of a multi-layered film, a half-width wavelength (λd, i.e., a cutoff frequency fc in the electric field) is shortened when an incident angle is increased. Accordingly, a change is caused in color reproducibility. In order to prevent this, it is advantageous that a size of the optical filter should be reduced as small as possible.

Also, the optical filter gives a mechanical strength to the image pickup device as the structural body in addition to the optical function. Also, the optical filter has an influence on a mounting precision. A Young's modulus of the glass as the base material is almost half of a silicon, and is high rather than a resin, and the like. Therefore, the optical filter is constructed to give a strength as the structural body. As a result, a positional precision becomes important to enhance a mechanical strength in the slimming down.

### Embodiment 6

Next, Embodiment 6 of the present invention will be explained hereunder. In Embodiment 6, as shown in a pertinent enlarged sectional view in FIG. 13 the case where the recess portion 18A of the plate-like member 18 is processed by the etching is illustrated. Like Embodiment 1, the present embodiment is characterized in that the optical filter 5 is fitted in the recess on the inside of the stepped portion to cover the opening, the wiring substrate 7 that has the hole corresponding to the optical filter 5 is fitted on the second surface 18a of the plate-like member 18, the semiconductor image pickup element 6 is mounted on this wiring substrate 7, the lens 2 is fitted on the first surface 18b of the plate-like member 18 such that the opening and the lens 2 overlap with each other in the optical axis direction, and a part of the first and second surfaces 18a, 18b is constructed by the surface 18c having the unevenness that is obtained y the etching. In this case, since the recess portion 18A is processed by the etching, no mechanical stress is applied to the plate-like holding member 18. Therefore, a precision of flatness can be improved.

Also, in the case of the press working, a level difference of the optical filter 5 and a level difference of the wiring substrate 7 are still kept. In contrast, in the case of shape process by the etching, a level difference of the optical filter 5 and a level difference of the wiring substrate 7 can be decided in magnitude freely, and a flexibility of design is enhanced. Further, a fine uneven surface is formed on the surface that is processed by the etching. This fine unevenness acts as an increase of a surface area when the optical filter 5, and the like are adhered/secured. An increase of the surface area can improve an adhesive property, and can enhance a adhesive strength. Accordingly, improvement of quality can be attained. The whole structure can be formed by the etching process. In this case, frames like the lead frames are shaped by the press working, and then only the stepped portion are formed by the etching process using a mask formed on both surfaces. As a result, the plate-like body can be formed extremely easily with good workability and with high dimensional precision.

Also, a fine uneven surface formed on the end surface of the opening portion 9 scatters a light. Accordingly, the ghost produced by a reflection at the end surface can be reduced. This corresponds to a situation that a matte coating is applied to the end surface to prevent a reflection. This can reduce the noise generated by the light transmitted through the back surface even when an image pickup element chip is slimmed down, and is effective particularly. According to such matte coating for reflection prevention, there is a possibility that a coating film is deteriorated due to an environmental change, a vibration impact, etc. to produce minutes cracks, etc., and then acts as the dusts to degrade a picture quality when the crack comes off, and the like. In contrast, since the base material never comes off from the fine unevenness produced by the etching, production of the dusts can be prevented and as a result the image pickup device of high quality can be realized.

### Embodiment 7

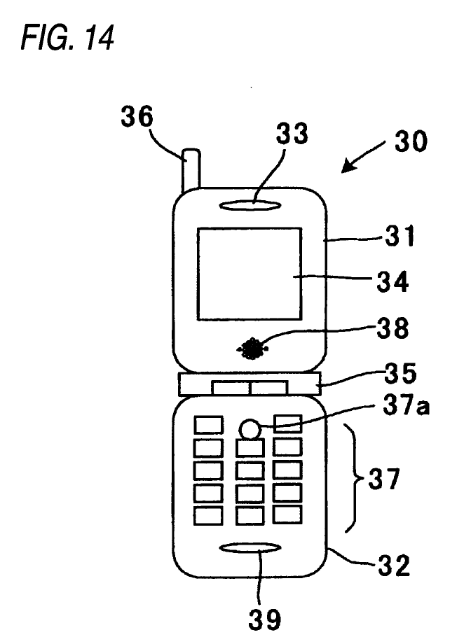

FIG. 14 is a plan view of a cellular phone 30 using the image pickup device in Embodiments 1 to 6 of the present invention. In the present embodiment, an example where the image pickup device of the present invention is installed into the folding cellular phone 30 is illustrated, and a size reduction and improvement of convenience are attained. In FIG. 14, the cellular phone 30 is constructed such that an upper case 31 and a lower case 32 can be folded via a hinge 35. A liquid crystal display screen 34, a speaker 33, an antenna 36 for transmission/reception, an image pickup device 38, and the like are installed into the upper case 31. An input key 37, a microphone 39, and the like are installed into the lower case 32. As the image pickup device 38, image pickup device 1 in Embodiment 1 of the present invention is employed. The shooting direction of the image pickup device 38 is set in the direction perpendicular to a sheet of FIG. 14. Such a mode is employed that the upper case 31 and the lower case 32 are opened in use, and these cases are closed in no use. A shooting operation is executed by pushing a shooting key 37a among the input key 37 to pick up an image. The slimming down of the cellular phone 30 can be achieved by installing the thin image pickup device.

For the purpose of weight reduction, when the plate-like member 8 used in the image pickup device 38 is made of aluminum, a weight of the plate-like member 8 can be reduced to ⅓ rather than the case where the plate-like member is made of SUS to have the same shape. Also, in order to prevent a reduction in a receiving sensitivity of the cellular phone 30, an electromagnetic shielding effect can be provided to the cellular phone 30 when the nickel silver including nickel as a major component, or the like is used as the plate-like member 8. The reason for this may be considered such that a noise cross talk caused due to communication state to the base station via a power feed line at a time of reception can be reduced. In addition to a weight reduction, the plate-like member 8 can be made multifunctional when nickel, silver, or the like is attached to the aluminum base by the plating, or the like to have the shielding effect. Also, the plate-like member can be made multifunctional by using a cladding material.

Also, since a weight reduction of the image pickup device 38 can enhance a strength against a drop impact, or the like, reliability of the cellular phone 30 can be improved. The mobile terminal device of the present invention is not limited to the above configuration, and the present invention can be applied to the mobile terminal device in various modes. For example, it is apparent that the present invention can be applied to the mobile terminal device such as PDA (Personal Digital Assistant), personal computer, external device of the personal computer, or the like. The present invention is not limited to the above embodiments, and can be carried out in various modes.

### INDUSTRIAL APPLICABILITY

In the image pickup device 1 of the present invention, the semiconductor image pickup element 6, the optical filter 5, and the lens 2 are positioned mutually by utilizing the stepped portion 8A of the plate-like member 8. Therefore, these components can be assembled on a basis of the stepped portion 8A and an optical axis can be set with good precision. Also, the plate-like member 8 and the optical filter 5 can be positioned to overlap with each other in the optical axis direction, and thus the slimming down of the image pickup device can be attained. Therefore, the image pickup device 1 of the present invention is useful for the camera application installed into the mobile terminal device such as the image pickup device, the cellular phone, or the like, and others.

1. An image pickup device, comprising:
a plate-like member equipped with an opening portion and having a stepped portion around the opening portion;
an optical filter provided on an inside of the stepped portion to cover the opening portion;
a wiring substrate arranged so as to be fitted on the stepped portion; and
an image pickup element mounted on the wiring substrate so that a light receiving face of the image pickup element is directed to an optical filter side.

2. The image pickup device according to claim 1, further comprising:
a lens positioned and attached to the plate-like member.

3. The image pickup device according to claim 2, wherein the image pickup element is flip-chip mounted on the wiring substrate.

4. The image pickup device according to claim 1, wherein the plate-like member is formed of a metal plate, and the stepped portion is obtained by a half die cutting.

5. The image pickup device according to claim 4, wherein the metal plate is formed of metal material including nickel as a major component.

6. The image pickup device according to claim 4, wherein the metal plate is formed of metal material including aluminum as a major component.

7. The image pickup device according to claim 1, wherein the optical filter is a reflection-type optical filter.

8. The image pickup device according to claim 1, wherein the stepped portion is obtained by an etching process.

9. A method of manufacturing an image pickup device, comprising:
providing a plate-like member that is equipped with an opening portion and has a stepped portion around the opening portion;
attaching an optical filter to the plate-like member to cover the opening portion on an inside of the stepped portion;
attaching a wiring substrate so as to be fitted on the stepped portion; and
mounting an image pickup device on the wiring substrate so that a light receiving face of the image pickup element is directed to an optical filter side,
wherein the process of attaching the optical filter includes:
filling an adhesive in an inner wall on an inside of the stepped portion; and
self-aligning the optical filter in accordance with a meniscus that is formed by the adhesive in a clearance between the inner wall of the stepped portion and the optical filter.

10. A mobile terminal device using the image pickup device set forth in claim 1.

11. An image pickup device, comprising:
a plate-like member equipped with an opening portion and having a recess portion around the opening portion on a first surface, and wherein a second surface opposing to the first surface is formed flat;
an optical filter positioned and fixed to the recess portion formed on the first surface to cover the opening portion;
a wiring substrate having an opening which corresponds to the opening portion in the plate-like member, and arranged so as to be fitted on the stepped portion; and
a semiconductor image pickup element mounted on the wiring substrate.

12. The image pickup device according to claim 11, wherein the optical filter is self-aligned in accordance with an adhesive that is filled in a clearance between the recess portion and the optical filter.

13. The image pickup device according to claim 11, further comprising:
a lens positioned and attached to the first surface of the plate-like member.

14. A method of manufacturing an image pickup device, comprising:
providing a plate-like member that is equipped with an opening portion and has a recess portion around the opening portion on a first surface, and wherein a second surface opposing to the first surface is formed flat;
attaching an optical filter to the recess portion formed in the first surface of the plate-like member to cover the opening portion;
attaching a wiring substrate to the second surface side of the plate-like member;
mounting an image pickup element on the wiring substrate so that a light receiving face of the image pickup element is directed to an optical filter side; and
attaching a lens to a first surface side of the plate-like member.

15. An image pickup device, comprising:
a plate-like member equipped with a stepped portion having an opening in a center of the stepped portion;
an optical filter arranged in a recess portion on an inside of the stepped portion to cover the opening;
a wiring substrate having an opening which corresponds to the optical filter, and arranged on a first surface of the plate-like member;
a semiconductor image pickup element mounted on the wiring substrate; and
a lens arranged on a second surface of the plate-like member.
wherein the opening and the lens are arranged to overlap with each other in an optical axis direction.

16. The image pickup device according to claim 15, wherein the optical filter is self-aligned in accordance with the adhesive that is filled in a clearance between the recess portion and the optical filter.

17. The image pickup device according to claim 15, wherein the wiring substrate has a hole that is fitted on an outer periphery of the optical filter fitted in a hole in the plate-like member, and is positioned by fitting the hole on the optical filter.

18. A method of manufacturing an image pickup device, comprising:
providing a plate-like member that is equipped with an opening portion in a center and has a stepped portion around the opening portion;
attaching an optical filter to a recess on an inside of the stepped portion of the plate-like member to cover the opening portion;
attaching a wiring substrate that has a hole corresponding to the optical filter so as to be arranged on a first surface of the plate-like member;
mounting an image pickup element on the wiring substrate so that a light receiving face of the image pickup element is directed to an optical filter side; and
attaching a lens so that the lens attached to a second surface of the plate-like member is able to overlap in an optical axis.
